(19) United States
(12) Patent Application Publication
(10) Pub. No.: US 2024/0164128 A1
(43) Pub. Date: May 16, 2024

(54) METHOD FOR PATTERNING NANOPARTICLE FILM, METHOD FOR MANUFACTURING LIGHT-EMITTING DEVICE, AND LIGHT-EMITTING DEVICE

(71) Applicant: SHARP KABUSHIKI KAISHA, Sakai City, Osaka (JP)

(72) Inventor: Yuma YAGUCHI, Sakai City, Osaka (JP)

(21) Appl. No.: 18/280,461

(22) PCT Filed: Mar. 9, 2021
(86) PCT No.: PCT/JP2021/009191

§ 371 Date: Sep. 5, 2023

(51) Int. Cl. H10K 50/115; C09K 11/02; C09K 11/54; C09K 11/88; H10K 71/15; H10K 71/20

(52) U.S. Cl. CPC H10K 50/115; C09K 11/02; C09K 11/54; C09K 11/88; H10K 71/15; H10K 71/20

(57) ABSTRACT

A first ligand containing one coordinating functional group allowing coordination to a first QD in a first EML patterned region of a first QD film is exchanged with a second ligand containing at least one kind of at least two coordinating functional groups allowing coordination to the first QD, the first QD film in a region other than the first EML patterned region is washed away and removed with a rinse liquid, and thus, the first QD film is patterned.

### TECHNICAL FIELD

The disclosure relates to a method for patterning a nanoparticle film to form a desired nanoparticle layer pattern by patterning the nanoparticle film, a method for manufacturing a light-emitting device by using the same, and a light-emitting device.

### BACKGROUND ART

In manufacturing a light-emitting device such as a light-emitting element by using a nanoparticle such as a quantum dot or an inorganic nanoparticle, patterning of a nanoparticle film containing a nanoparticle is performed. As a method for forming a desired nanoparticle layer pattern by patterning a nanoparticle film, a method for patterning that uses a photoresist is known.

For example, PTL 1 discloses forming a desired quantum dot pattern by applying a photosensitive composition containing a quantum dot, a binder, and constituent components of an alkali-developable photoresist onto a substrate to form a film, exposing the film by using a mask, and then developing the film.

### CITATION LIST

### Patent Literature

PTL 1: JP 2017-83837 A

### Non Patent Literature

NPL 1: Yu-Ho Won, and nine others, Highly efficient and stable InP/ZnSe/ZnS quantum dot light-emitting diodes, Nature Vol 575, Nov. 28, 2019, p. 634-638

### SUMMARY OF INVENTION

### Technical Problem

However, ultraviolet light is typically used for exposing the photoresist. When the nanoparticle film is irradiated with ultraviolet light in order to pattern the nanoparticle film, deterioration is likely to occur in the formed nanoparticle layer pattern.

An aspect of the disclosure has been made in view of the above-described problem, and an object thereof is to provide a method for patterning a nanoparticle film that does not require irradiation with ultraviolet light and that can suppress deterioration of a nanoparticle layer pattern to be formed, and a method for manufacturing a light-emitting device using the same. Further, another object of an aspect of the disclosure is to provide a light-emitting device including a nanoparticle layer pattern that does not require irradiation with ultraviolet light and in which deterioration is suppressed.

### Solution to Problem

In order to solve the problem described above, a method for patterning a nanoparticle film according to an aspect of the disclosure includes first nanoparticle film forming of forming a first nanoparticle film on a support body, the first nanoparticle film containing a first nanoparticle and a first ligand, the first ligand containing one coordinating functional group allowing coordination to the first nanoparticle, first ligand exchanging of bringing a first solution into contact with a first nanoparticle layer patterned region that is a part of the first nanoparticle film, the first solution containing a second ligand containing at least one kind of at least two coordinating functional groups allowing coordination to the first nanoparticle, to exchange the first ligand coordinated to the first nanoparticle in the first nanoparticle layer patterned region with the second ligand, and first washing of washing the first nanoparticle film with a first washing liquid to wash away and remove the first nanoparticle film in a region other than the first nanoparticle layer patterned region, the first nanoparticle film in the region not being brought into contact with the first solution, thereby forming a first nanoparticle layer pattern.

In order to solve the problem described above, a method for manufacturing a light-emitting device according to an aspect of the disclosure, the light-emitting device including, between the first electrode and the second electrode, a first electrode and a second electrode, and at least one layer including a nanoparticle layer pattern containing a nanoparticle, includes forming at least one layer of the at least one layer including the nanoparticle layer pattern by the method for patterning a nanoparticle film according to the aspect of the disclosure.

In order to solve the problem described above, a light-emitting device according to an aspect of the disclosure includes a support body, and a plurality of first nanoparticle layer patterns spaced apart from each other on the support body, and each of the plurality of first nanoparticle layer patterns includes a plurality of first nanoparticles and a ligand, the ligand containing at least one kind of at least two coordinating functional groups allowing coordination to the plurality of first nanoparticles.

### Advantageous Effects of Invention

When the first ligand coordinated to the first nanoparticle is exchanged with the second ligand, the first nanoparticle coordinated with the second ligand is cured and insolubilized in the first washing liquid. Thus, when the first nanoparticle film is washed with the first washing liquid, the first nanoparticle film in the region other than the first nanoparticle layer patterned region, the first nanoparticle film in the region not being brought into contact with the first solution, the first nanoparticle film in the region not being subjected to the exchanging of the first ligand, is washed away and removed with the first washing liquid. As a result, according to the aspect of the disclosure, the method for patterning a nanoparticle film that does not require irradiation with ultraviolet light and that can suppress deterioration of the nanoparticle layer pattern to be formed can be provided.

In addition, according to the above-described method, since the nanoparticle layer pattern having high liquid resistance to the first washing liquid and being capable of suppressing deterioration can be formed, the light-emitting device having higher absorbance and higher light emission intensity than those of conventional devices can be manufactured. Thus, according to the aspect of the disclosure, the method for manufacturing the light-emitting device that can suppress deterioration of the first nanoparticle layer pattern to be formed without requiring irradiation with ultraviolet light and that can manufacture the light-emitting device having excellent light-emission characteristics can be provided. Further, according to the aspect of the disclosure, it is possible to provide the light-emitting device having excellent light-emission characteristics and including the first nanoparticle layer pattern that does not require irradiation with ultraviolet light and in which deterioration is suppressed.

### BRIEF DESCRIPTION OF DRAWINGS

FIG. 1 is a cross-sectional view illustrating an example of a schematic configuration of a light-emitting element according to a first embodiment.

FIG. 2 is a flowchart illustrating an example of an outline of a method for manufacturing the light-emitting element according to the first embodiment.

FIG. 3 is a flowchart illustrating an example of an EML forming process using a method for patterning a nanoparticle film according to the first embodiment.

FIG. 4 is cross-sectional views illustrating a part of the EML forming process illustrated in FIG. 3 in order of the process.

FIG. 5 is a flowchart illustrating an example of a first QD film forming process illustrated in FIG. 3.

FIG. 6 is a graph illustrating a relationship between a film thickness of the first QD film after washing and the number of times of washing in each of Examples 1 and 2 and Comparative Example 1.

FIG. 7 is a graph illustrating a relationship between an absorbance of the first QD film after washing with respect to light having a wavelength of 450 nm and the number of times of washing in each of Example 1 and Comparative Example 1.

FIG. 8 is a graph illustrating a relationship between an absorbance of the first QD film after washing with respect to light having a wavelength of 450 nm after washing and the number of times of washing in each of Example 2 and Comparative Example 1.

FIG. 9 is a graph illustrating a relationship between a light emission intensity of the first QD film after washing with respect to light having a wavelength of 450 nm after washing and the number of times of washing in each of Example 1 and Comparative Example 1.

FIG. 10 is a graph illustrating a relationship between a light emission intensity of the first QD film after washing with respect to light having a wavelength of 450 nm after washing and the number of times of washing in each of Example 2 and Comparative Example 1.

FIG. 11 is a cross-sectional view illustrating an example of a schematic configuration of main portions of a light-emitting element according to a second embodiment.

FIG. 12 is a flowchart illustrating an example of an EML forming process using a method for patterning a nanoparticle film according to the second embodiment.

FIG. 13 is cross-sectional views illustrating a part of the EML forming process illustrated in FIG. 12 in order of the process.

FIG. 14 is a flowchart illustrating an example of a second QD film forming process illustrated in FIG. 12.

FIG. 15 is cross-sectional views illustrating another part of the EML forming process illustrated in FIG. 12 in order of the process.

FIG. 16 is a flowchart illustrating an example of a third QD film forming process illustrated in FIG. 12.

FIG. 17 is a cross-sectional view illustrating an example of a schematic configuration of main portions of a display device according to a third embodiment.

### DESCRIPTION OF EMBODIMENTS

### First Embodiment

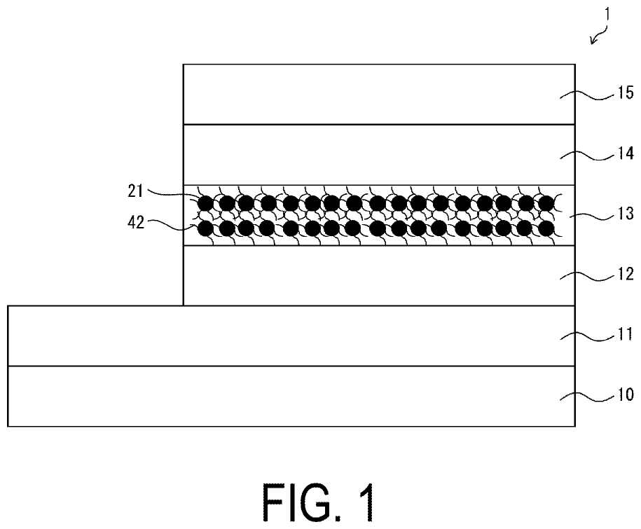

One aspect of an embodiment of the disclosure will be described as follows based on FIG. 1 to FIG. 10. Note that, in the following, description of “from A to B” for two numbers A and B means “being equal to or greater than A and equal to or less than B”, unless otherwise specified.

A nanoparticle film according to the present embodiment is not particularly limited as long as the nanoparticle film is a film containing a nanoparticle. Thus, a nanoparticle layer pattern formed by patterning the nanoparticle film is not particularly limited as long as the nanoparticle layer pattern is a patterned layer containing a nanoparticle. Examples of a light-emitting device including such a nanoparticle layer pattern include a light-emitting element, a display device, and an illumination (light source) device. Further, examples of the nanoparticle layer pattern in such a light-emitting device include a light-emitting layer, a layer having carrier transport properties such as a carrier transport layer or a carrier injection layer that transports or injects a carrier into the light-emitting layer, and a wavelength conversion layer in a wavelength conversion member such as a wavelength conversion film provided in the light-emitting device, and the exemplified layers contain nanoparticles.

Hereinafter, an example of a method for patterning a nanoparticle film according to the present embodiment will be described with reference to a method for manufacturing a light-emitting element. Hereinafter, the method for patterning described above is applied to formation of a quantum dot light-emitting layer of the light-emitting element. That is, in the present embodiment, a case where a nanoparticle (first nanoparticle) is a quantum dot and a nanoparticle layer pattern (first nanoparticle layer pattern) formed by patterning a nanoparticle film (first nanoparticle film) is a quantum dot light-emitting layer will be described as an example. Note that, hereinafter, the quantum dot is referred to as “QD”, and the quantum dot light-emitting layer is referred to as “EML” (or “QD light-emitting layer”).

Here, first of all, an outline of an example of a layered structure of a light-emitting element and a method for manufacturing the light-emitting element according to the present embodiment will be described.

FIG. 1 is a cross-sectional view illustrating an example of a schematic configuration of a light-emitting element 1 according to the present embodiment.

The light-emitting element 1 illustrated in FIG. 1 is an electroluminescent element that emits light when a voltage is applied to an EML 13. Examples of the light-emitting element 1 include a quantum dot light emitting diode (QLED). Note that the light-emitting element 1 may be used as, for example, a light source of a light-emitting device such as a display device or an illumination device.

As illustrated in FIG. 1, the light-emitting element 1 includes an anode electrode 11 (anode, first electrode) and a cathode electrode 15 (cathode, second electrode) that are positioned so as to be opposed to each other, and a function layer provided between the anode electrode 11 and the cathode electrode 15. The function layer includes at least the EML 13. Note that, in the present embodiment, layers between the anode electrode 11 and the cathode electrode 15 are collectively referred to as the function layer.

The function layer may be a single layer type formed only of the EML 13, or may be a multi-layer type including other function layers in addition to the EML 13. Of the function layer, examples of the function layers other than the EML 13 include a hole transport layer, and an electron transport layer. Hereinafter, the hole transport layer is referred to as “HTL”, and the electron transport layer is referred to as “ETL”.

Note that each layer from the anode electrode 11 to the cathode electrode 15 is generally formed on a substrate 10 used as a support body. Accordingly, the light-emitting element 1 may be provided with the substrate 10 as a support body.

As one example, the light-emitting element 1 illustrated in FIG. 1 has a configuration in which the anode electrode 11, an HTL 12, the EML 13, an ETL 14, and the cathode electrode 15 are layered in this order on the substrate 10. The ETL 14 is layered adjacent to the EML 13 on the EML 13. The anode electrode 11 and the cathode electrode 15 are connected to a power supply (not illustrated) (for example, a direct current power supply) so that a voltage is applied between the anode electrode 11 and the cathode electrode 15.

Note that, in the present embodiment, a direction extending from the substrate 10 toward the cathode electrode 15 is referred to as an upward direction, and the opposite direction thereto is referred to as a downward direction. In addition, in the present embodiment, a “lower layer” means a layer that is formed in a process prior to that of a layer to be compared, and an “upper layer” means a layer that is formed in a process after that of a layer to be compared.

Note that the configuration of the light-emitting element 1 is not limited to the configuration described above. In FIG. 1, a case in which a lower layer electrode provided on the substrate 10 is the anode electrode 11 and an upper layer electrode provided above the lower layer electrode is the cathode electrode 15 is illustrated as an example. However, the lower layer electrode may be the cathode electrode 15, the upper layer electrode may be the anode electrode 11, and the cathode electrode 15, the ETL 14, the EML 13, the HTL 12, and the anode electrode 11 may be layered in this order on the substrate 10.

Additionally, the light-emitting element 1 may include a layer other than the HTL 12, the EML 13, and the ETL 14 as the function layer. As an example, the light-emitting element 1 may include a hole injection layer (HIL) between the anode electrode 11 and the HTL 12. In addition, for example, when the light-emitting element 1 includes the ETL 14 as illustrated in FIG. 1, the light-emitting element 1 may include an electron injection layer (EIL) between the ETL 14 and the cathode electrode 15. A hole transport material, which will be described later, can be used for the HIL. An electron transport material, which will be described later, can be used for the EIL.

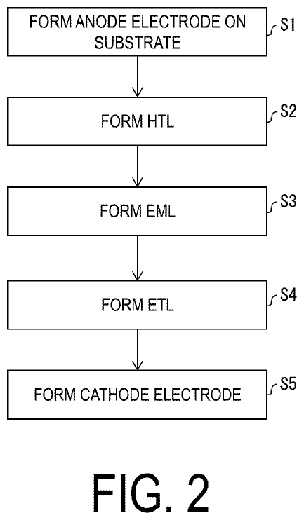

FIG. 2 is a flowchart illustrating an example of an outline of a method for manufacturing the light-emitting element 1 according to the present embodiment.

As illustrated in FIG. 2, in a manufacturing process of the light-emitting element 1 according to the present embodiment, for example, first, the anode electrode 11 is formed on the substrate 10 as an example (step S1: an anode electrode forming process). Next, the HTL 12 is formed on the anode electrode 11 (step S2: an HTL forming process). Subsequently, the EML 13 is formed on the HTL 12 (step S3: an EML forming process). Then, the ETL 14 is formed on the EML 13 (step S4: an ETL forming process). Subsequently, the cathode electrode 15 is formed on the ETL 14 (step S5: a cathode electrode forming process). Note that after formation of the cathode electrode 15 in step S5, the layered body (from the anode electrode 11 to the cathode electrode 15) formed on the substrate 10 may be sealed with a sealing member.

The substrate 10 is a support body for forming the layers from the anode electrode 11 to the cathode electrode 15. The substrate 10 may be, for example, a glass substrate, or may be a flexible substrate such as a plastic substrate, or a plastic film. Additionally, when the light-emitting element 1 is a part of a light-emitting device including a plurality of light-emitting elements 1, the substrate 10 may be an array substrate including a thin film transistor layer provided with a plurality of thin film transistors (drive elements) for driving the plurality of light-emitting elements 1 as a drive circuit layer.

In formation of the anode electrode 11 and the cathode electrode 15 in step S1 and step S5, for example, a sputtering technique, a film vapor deposition technique, a vacuum vapor deposition technique, or a physical vapor deposition (PVD) technique may be used. Note that a mask (not illustrated) may be used to form the anode electrode 11 or the cathode electrode 15, or each electrode material may be formed into a solid film, and then patterned into a desired shape as necessary. For example, when the light-emitting element 1 is a part of a display device, the anode electrode 11 may be formed for each pixel by forming an anode material (electrode material) into a solid film and then patterning the film.

The anode electrode 11 is an electrode that supplies a positive hole (hole) to the EML 13 when being applied with a voltage. The cathode electrode 15 is an electrode that supplies an electron to the EML 13 when being applied with a voltage.

At least one of the anode electrode 11 and the cathode electrode 15 is formed of a light-transmissive material. Note that any one of the anode electrode 11 and the cathode electrode 15 may be formed of a material having light reflectivity. The light-emitting element 1 can extract light from the electrode side formed of the light-transmissive material.

The anode electrode 11 is made of, for example, a material having a relatively large work function. Examples of the material include tin-doped indium oxide (ITO), zinc-doped indium oxide (IZO), aluminum-doped zinc oxide (AZO), gallium-doped zinc oxide (GZO), and antimony-doped tin oxide (ATO). A single type of these materials may be used alone, or two or more types may be mixed and used, as appropriate.

The cathode electrode 15 is made of, for example, a material having a relatively small work function. Examples of the material include Al, silver (Ag), Ba, ytterbium (Yb), calcium (Ca), lithium (Li)—Al alloys, Mg—Al alloys, Mg—Ag alloys, Mg-indium (In) alloys, and Al-aluminum oxide (Al₂O₃) alloys.

For example, a sputtering technique, a vacuum vapor deposition technique, PVD, a spin coating technique, or an ink-jet technique is used for formation of the HTL 12 in step S2 and formation of the ETL 14 in step S4.

The HTL 12 is a layer that transports a positive hole supplied from the anode electrode 11 to the EML 13. Examples of a material of the HTL 12 include polymer materials having electrical conductivity and hole transport properties.

For example, the HTL 12 may include an organic material such as poly(3,4-ethylenedioxythiophene) (PEDOT), poly(3,4-ethylenedioxythiophene)-poly(styrenesulfonic acid) (PEDOT-PSS), poly(N-vinylcarbazole) (PVK), poly[(9,9-dioctylfluorenyl-2,7-diyl)-co-(4,4′-(N-(4-sec-butylphenyl))diphenylamine)](TFB), 4,4′-bis(9-carbazolyl)-biphenyl (CBP), and N,N′-di-[(1-naphthyl)-N,N′-diphenyl]-(1,1′-biphenyl)-4,4′-diamine (NPD), or derivatives of compounds described above, as the polymer material described above.

In addition, the HTL 12 may be formed of an inorganic material, or may contain an inorganic material. Examples of the inorganic material described above include inorganic compounds such as p-type semiconductors. Examples of the p-type semiconductor described above include metal oxide, group IV semiconductors, group II-VI compound semiconductors, group III-V compound semiconductors, amorphous semiconductors, and thiocyanic acid compounds. Examples of the metal oxide described above include nickel oxide (NiO), titanium oxide (TiO₂), molybdenum oxide (MoO₂, MoO₃), magnesium oxide (MgO), and lanthanum nickel oxide (LaNiO₃). Examples of the group IV semiconductor described above include silicon (Si), and germanium (Ge). Examples of the group II-VI compound semiconductor described above include zinc sulfide (ZnS), and zinc selenide (ZnSe). Examples of the group III-V compound semiconductor described above include aluminum arsenide (AlAs), gallium arsenide (GaAs), indium arsenide (InAs), aluminum nitride (AlN), gallium nitride (GaN), indium nitride (InN), and gallium phosphide (GaP). Examples of the amorphous semiconductor described above include p-type hydrogenated amorphous silicon, and p-type hydrogenated amorphous silicon carbide. Examples of the thiocyanic acid compound described above include thiocyanates such as copper thiocyanate. Among these hole transport materials, only one type may be used. Two or more types of these hole transport materials may appropriately be mixed and used, or mixed crystal of these hole transport materials may be used.

It is desirable for the above hole transport materials to be inorganic particles, and more desirable to be fine particles (inorganic nanoparticles) formed of the above-exemplified inorganic compounds because these particles are excellent in durability and in reliability, and the film formation can be carried out by a coating method and is easy to carry out. Among them, fine particles (nanoparticles) of metal oxide are particularly desirable for the hole transport material described above. Note that the metal oxide described above may be a mixed crystal of metal oxides.

The ETL 14 is a layer that transports an electron supplied from the cathode electrode 15 to the EML 13. When the ETL 14 is an inorganic material, examples of the inorganic material include inorganic compounds such as n-type semiconductors. Examples of the n-type semiconductor described above include metal oxide, group II-VI compound semiconductors, group 111-V compound semiconductors, group IV-IV compound semiconductors, and amorphous semiconductors. Examples of the metal oxide described above include zinc oxide (ZnO), titanium oxide (TiO₂), indium oxide (In₂O₃), tin oxide (SnO, SnO₂), and cerium oxide (CeO₂). Examples of the group II-VI compound semiconductor described above include zinc sulfide (ZnS), and zinc selenide (ZnSe). Examples of the group III-V compound semiconductor described above include aluminum arsenide (AlAs), gallium arsenide (GaAs), indium arsenide (InAs), aluminum nitride (AlN), gallium nitride (GaN), indium nitride (InN), and gallium phosphide (GaP). Examples of the group IV-IV compound semiconductor described above include silicon germanium (SiGe), and silicon carbide (SiC). Examples of the amorphous semiconductor described above include n-type hydrogenated amorphous silicon. Only one type of material among these electron transport materials may be used, two or more types may be mixed and used as appropriate, or a mixed crystal-based material of these electron transport materials may be used.

It is desirable for the above electron transport materials to be inorganic particles, and more desirable to be fine particles (inorganic nanoparticles) formed of the above-exemplified inorganic compounds because these electron transport materials are excellent in durability and in reliability, and film formation can be carried out by a coating method and is easy to carry out. Among them, it is particularly desirable for the electron transport materials described above, similar to the hole transport materials, to be metal oxide nanoparticles (in other words, fine particles of metal oxide or mixed crystal-based fine particles of the metal oxide).

On the other hand, when the ETL 14 is made of an organic material, examples of the organic material include 1,3,5-tris(1-phenyl-1H-benzimidazol-2-yl)benzene (TPBi), 3-(biphenyl-4-yl)-5-(4-tert-butylphenyl)-4-phenyl-4H-1,2,4-triazole (TAZ), bathophenanthroline (Bphen), and tris(2,4,6-trimethyl-3-(pyridine-3-yl)phenyl)borane (3TPYMB), or derivatives of the compounds described above.

The EML 13 is a light-emitting layer (for example, a QD phosphor layer) containing a QD and a ligand. The ligand is positioned (coordinated) on the surface of the QD with the QD functioning as a receptor.

In the light-emitting element 1, a positive hole and an electron recombine inside the EML 13 in response to a drive current between the anode electrode 11 and the cathode electrode 15, and light (for example, fluorescence or phosphorescence) is emitted when an exciton generated due to the recombination transitions from the conduction band level to the valence band level of the QD.

QDs are a luminescent material that has a valence band level and a conduction band level and that emits light due to recombination of a positive hole at the valence band level with an electron at the conduction band level. The QD is also referred to as a semiconductor nanoparticle.

As illustrated in FIG. 1, the EML 13 (first nanoparticle layer pattern) according to the present embodiment contains a first QD 21 (first nanoparticle) as the nanoparticle and a second ligand 42 as the ligand.

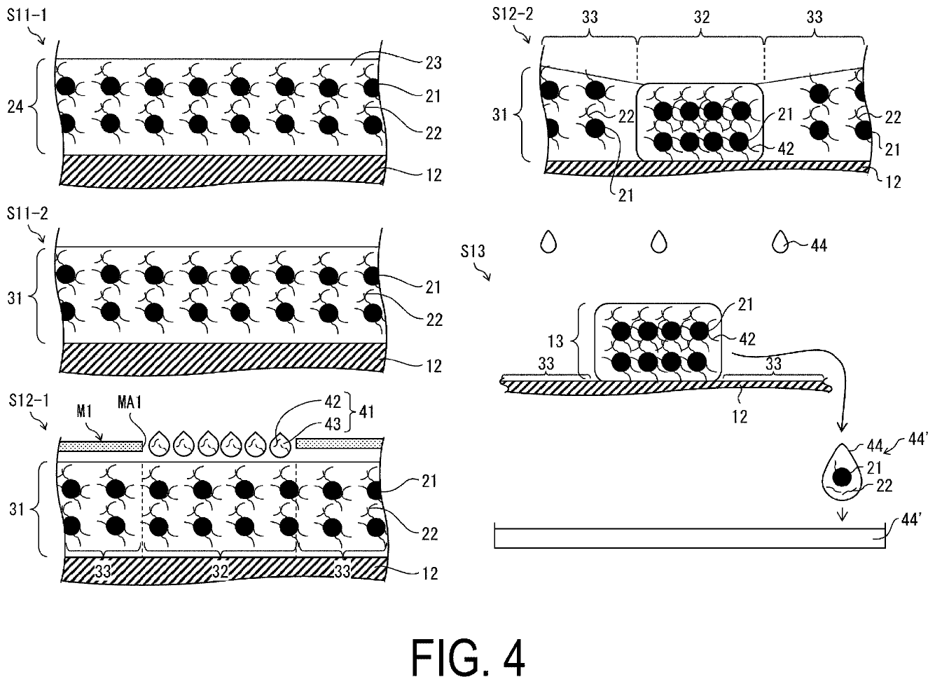

Although the details will be described later, the EML 13 is formed by replacing first ligands 22 that are a part of a first QD film 31 formed by applying a colloidal solution 24 (first colloidal solution) illustrated in FIG. 4, which will be described later, with second ligands 42, and then performing washing (developing). The colloidal solution 24 contains the first QD 21 (first nanoparticle) that is a nanoparticle, the first ligand 22, and a solvent 23 (first solvent) that dissolves the first ligand 22.

The first QD 21 is not particularly limited, and known various types of QDs may be employed. Examples of the first QD 21 described above include a QD phosphor.

The first QD 21 may include, for example, a semiconductor material formed of at least one type of element selected from the group consisting of Cd (cadmium), S (sulfur), Te (tellurium), Se (selenium), Zn (zinc), In (indium), N (nitrogen), P (phosphorus), As (arsenic), Sb (antimony), Al (aluminum), Ga (gallium), Pb (lead), Si (silicon), Ge (germanium), and Mg (magnesium). Note that a typical QD contains Zn. Thus, the first QD 21 may be, for example, a semiconductor material containing a Zn atom.

Further, the first QD 21 may be a two-component core type, a three-component core type, a four-component core type, a core-shell type, or a core-multi-shell type. Further, the first QD 21 may contain a doped nanoparticle, or may have a compositionally graded structure in which composition gradually changes. In the present embodiment, the first QD 21 is, for example, a core-shell type QD having a core-shell structure including a core and a shell as illustrated in Examples, which will be described later as an example. For example, a nano-sized crystal of the semiconductor material described above can be used for the core. The shell is provided outside the core so as to cover the core.

As an example, a particle diameter (diameter) of the core is, for example, approximately from 1 to 10 nm. Even when the shell is included, an outermost particle diameter of the first QD 21 is, for example, approximately from 1 to 15 nm, and preferably approximately from 3 to 15 nm. The number of overlapping layers of the first QD 21 in the EML 13 is, for example, from 1 to 10. As a film thickness of the EML 13, a conventionally known film thickness can be employed, for example, the film thickness is within a range of about 1 to 150 nm, and preferably within a range of 3 to 150 nm. Note that in the present embodiment, the “particle diameter” refers to a “number average particle diameter” unless otherwise specified.

Note that, in such a core-shell type QD, a wavelength of light emitted by the QD is proportional to the particle diameter of the core, and does not depend on the outermost particle diameter of the QD including the shell.

The second ligand 42 is a surface modifier that modifies the surface of the first QD 21 by coordinating the second ligand 42 to the surface of the first QD 21 with the first QD 21 serving as a receptor. In the present embodiment, a monomer that is a compound having a molecular weight being 1000 or less is used as the second ligand 42. Note that by performing mass spectrometry of a nanoparticle film or a nanoparticle layer pattern containing the second ligand 42 by using a time-of-flight secondary ion mass spectrometry method (TOF-SIMS) or the like, the molecular structure of a ligand (to be specific, the molecular structure of the second ligand 42) contained in the nanoparticle film or the nanoparticle layer pattern (for example, the EML 13) can be determined with high accuracy. For the second ligand 42, a monomer containing at least one kind of at least two coordinating functional groups (adsorbing groups) for coordination (adsorption) to the first QD 21 is used.

The second ligand 42 is desirably, for example, a monomer containing the at least two coordinating functional groups, and a substituted or unsubstituted alkylene group or a substituted or unsubstituted unsaturated hydrocarbon group as a spacer (spacer group) bonded to these coordinating functional groups and positioned between these coordinating functional groups. Here, note that the substituted or unsubstituted alkylene group refers to an alkylene group that may be unsubstituted or that may have a substituent. Similarly, the substituted or unsubstituted unsaturated hydrocarbon group refers to an unsaturated hydrocarbon group that may be unsubstituted or that may have a substituent. Additionally, here, the expression “may have a substituent” includes both a case in which a hydrogen atom (—H) is substituted by a monovalent group and a case in which a methylene group (—CH₂—) is substituted by a divalent group.

The alkylene group described above may be chain-like or cyclic. In addition, the unsaturated hydrocarbon group described above may be an aliphatic hydrocarbon group or an aromatic hydrocarbon group.

Examples of the substituent described above include an aliphatic hydrocarbon group, an aromatic hydrocarbon group, an aromatic heterocyclic group, and a hydroxyl group. In addition, the hydrogen atom may be substituted with the coordinating functional group described above.

Further, the second ligand 42 may contain at least one kind of at least two coordinating functional groups, and at least one kind of at least one polar bonding group at a site other than a site coordinated to the first QD 21.

The coordinating functional group described above is not particularly limited as long as the coordinating functional group is a functional group capable of being coordinated to the first QD 21, and examples thereof include at least one kind of a functional group selected from the group consisting of a thiol (—SH) group, an amino (—NR₂) group, a carboxyl (—C(═O)OH) group, a phosphone (—P(═O)(OR)₂) group, a phosphine (—PR₂) group, and a phosphineoxide (—P(═O)R₂) group. Note that the R groups described above are independent of each other, and represent a hydrogen atom or any organic group such as an alkyl group or an aryl group. The amino group described above may be any of primary, secondary, and tertiary amino groups, and among them, a primary amino (—NH₂) group is particularly preferable. Additionally, the phosphone group, the phosphine group, and the phosphine oxide group that have been described above may be any of primary, secondary, and tertiary groups, but the phosphone group, the phosphine group, and the phosphine oxide group are particularly preferably a tertiary phosphone (—P(═O)(OR)₂) group, a tertiary phosphine (—PR₂) group, and a tertiary phosphine oxide (—P(═O)R₂) group in which the R group described above is an alkyl group, respectively. Note that examples of the alkyl group described above in the tertiary phosphone group, the tertiary phosphine group, and the tertiary phosphine oxide group include an alkyl group having 1 to 20 carbons.

As described above, a typical QD contains Zn. For example, as illustrated in Examples, which will be described later, the shell (outermost surface) contains Zn. The thiol group has a high coordination property to a nanoparticle containing Zn compared with an amino group, a carboxyl group, a phosphone group, a phosphine group, and a phosphine oxide group. Thus, the second ligand 42 described above preferably contains a thiol group as the coordinating functional group described above, and each of the coordinating functional groups contained in the second ligand 42 is more preferably a thiol group.

In addition, the polar bonding group is not particularly limited as long as the polar bonding group is a bonding group that imparts polarity to the second ligand 42 (that is, a bonding group that imparts bias of charge distribution in bonding to the second ligand 42), and examples thereof include at least one bonding group selected from the group consisting of an ether bonding (—O—) group, a sulfide bonding (—S—) group, an imine bonding (—NH—) group, an ester bonding (—C(═O)O—) group, an amide bonding (—C(═O)NR′—) group, and a carbonyl (—C(═O)—) group. Note that the R′ group represents a hydrogen atom or any organic group such as an alkyl group or an aryl group.

Note that when the second ligand 42 contains a polar bonding group as described above, the second ligand 42 preferably contains an alkylene group having 1 to 4 carbons, the alkylene group being directly bonded to the polar bonding group.

When a distance between the first QDs 21 with the second ligand 42 interposed therebetween is too short, deactivation of the first QDs 21 may occur. In a case where the second ligand 42 contains a polar bonding group as described above, the second ligand 42 contains an alkylene group having 1 to 4 carbons, the alkylene group being directly bonded to the polar bonding group, which suppresses a decrease in light-emission characteristics due to deactivation of the first QDs 21.

Examples of the second ligand 42 described above include a monomer containing the coordinating functional groups, which may be the same as or different from each other, at both ends of a main chain. As the second ligand 42 as described above, for example, at least one kind of ligand selected from the group consisting of ligands represented by the following general formula (1) and the following general formula (2) is exemplified.

R¹-A¹-A²-(CH₂)ₙ—R² (1)

R³—Z—R⁴ (2)

Note that in the general formula (1) described above, each of R¹ and R² independently represents the coordinating functional group. In other words, R¹ and R² may be the same coordinating functional group as each other or may be different coordinating functional groups from each other. A¹ represents a substituted or unsubstituted —((CH₂)ₘ₁—X¹)ₘ₂-group. A² represents a direct bond, an X² group, or a substituted or unsubstituted —((CH₂)ₘ₃—X²)ₘ₄-group. X¹ and X² represent polar bonding groups different from each other. Each of n and m1 to m4 independently represents an integer of 1 or more. Note that each of n, m1, and m3 is desirably independently an integer of 1 to 4, and each of m2 and m4 is desirably independently an integer of 1 to 10.

Additionally, substituted or unsubstituted —((CH₂)ₘ₁—X¹)ₘ₂-group indicates that —((CH₂)ₘ₁—X¹)ₘ₂-group may be unsubstituted or may contain a substituent. Similarly, substituted or unsubstituted —((CH₂)ₘ₃—X²)ₘ₄-group indicates that —((CH₂)ₘ₃—X²)ₘ₄-group may be unsubstituted or may contain a substituent.

As described above, the expression “may contain a substituent” includes both a case in which a hydrogen atom (—H) is substituted by a monovalent group and a case in which a methylene group (—CH₂—) is substituted by a divalent group.

Note that even in the case where the alkylene group is bonded to the polar bonding group as described above, the alkylene group described above may be chain-like or may be cyclic. Thus, —((CH₂)ₘ₁—X¹)ₘ₂-group and —((CH₂)ₘ₃—X²)ₘ₄-group may be chain-like or may be cyclic.

Note that as described above, examples of the substituent described above include an aliphatic hydrocarbon group, an aromatic hydrocarbon group, an aromatic heterocyclic group, and a hydroxyl group. In addition, the hydrogen atom may be substituted with the coordinating functional group described above. Thus, the ligand represented by the general formula (1) may be a bifunctional molecule containing the coordinating functional groups, which may be the same as or different from each other, at both ends of the main chain, or may be a polyfunctional molecule containing the coordinating functional groups at the both ends of the main chain and at the side chain.

Further, in the general formula (2) described above, each of R³ and R⁴ independently represents the coordinating functional group described above. In other words, R³ and R⁴ may be the same coordinating functional group as each other or may be different coordinating functional groups from each other. Z represents a substituted or unsubstituted alkylene group having 1 to 10 carbons, or a substituted or unsubstituted unsaturated hydrocarbon group having 2 to 10 carbons.

By using the ligand described above as the second ligand 42, the EML 13 in which the second ligand 42 described above is coordinated to the at least two first QD 21, liquid resistance to polar solvents and non-polar solvents (apolar solvents) is high, and deterioration in patterning is suppressed can be formed as the first nanoparticle layer pattern.

Note that this effect is unique to the case where the second ligand 42 is a monomer. A polymer, in which a structure (monomer) as a unit is repeated many times, generally has about 1,000 or more atoms or is polymerized to have a molecular weight being equal to or more than 10000. Additionally, an oligomer, in which a structure (monomer) as a unit is repeated a small number of times, generally has a molecular weight from 1000 to 10000. The polymerized or oligomerized ligand consumes the coordinating functional group such as thiol that can be coordinated to a nanoparticle (the first QD 21 in the present embodiment) to form a chain due to chemical reactions. Thus, as the molecules become larger, the amount or density of the coordinating functional groups that can be coordinated to the nanoparticles decreases. For this reason, the polymerized or oligomerized ligand becomes a factor that greatly decreases the room or probability capable of coordination to the nanoparticle and the probability of exhibiting the effect of insolubilization that connects the nanoparticles to each other.

In the present embodiment, the number of atoms constituting a linear chain of the second ligand 42 described above is desirably substantially the same as the number of atoms constituting a linear chain of a conventionally used ligand even when the second ligand 42 contains a polar bonding group as described above. In addition, the number of molecules of the second ligand 42 described above is preferably not so large so as to be easily dissolved (dispersed) in a non-polar solvent.

Thus, in the case where A² described above indicates a direct bond, the ligand represented by the general formula (1) described above preferably satisfies 2≤m1×m2+n≤20, and more preferably satisfies 3≤m1×m2+n≤10.

In a case where a distance between the nanoparticles (in the present embodiment, the first QDs 21) with the second ligand 42 interposed therebetween is too short, when the nanoparticles are the QDs as described above, interaction between the QDs occurs to cause transfer of electrons between the QDs, and the QDs are deactivated, which causes a decrease in luminous efficiency and a decrease in light emission intensity.

According to NPL 1, when a distance between the cores of the QDs is about 9 nm, Forster resonance energy transfer (FRET) efficiency is equal to or less than about 6%. This indicates that the FRET is suppressed when the distance between the cores of the QDs is about 9 nm. In addition, thicknesses of the shells of general commercial QDs are about 1 to 2 nm. Thus, when a distance including the shells between the QDs adjacent to each other (in other words, a distance between the outer surfaces of the shells of the QDs adjacent to each other) is greater than or equal to 5 nm, the FRET effect can be reduced.

Accordingly, in order to prevent deactivation of the first QDs 21, the shortest distance between the first QDs 21 adjacent to each other is preferably equal to or longer than 5 nm. On the other hand, when the shortest distance between the first QDs 21 that are adjacent to each other is long, a rate of the first QDs 21 in the EML 13 is small, and the luminous efficiency is low. As a result, the light emission intensity is reduced. Thus, when the first nanoparticle layer pattern is, for example, an EML as described above, the distance between the first QDs 21 adjacent to each other is desirably equal to or less than 20 nm. When the first nanoparticle layer pattern is, for example, a QD wavelength conversion layer in a wavelength conversion member, which will be described later, the distance between the first QDs 21 adjacent to each other is desirably equal to or less than 50 nm.

Note that the distance between the QDs (nanoparticles, the first QDs 21 in the present embodiment) adjacent to each other is a value obtained by subtracting a number average particle diameter of the QDs from an average value of distances between the centers of the QDs adjacent to each other (referred to as an average QD center-to-center distance). The average QD center-to-center distance can be measured by using, for example, a small angle X-ray scattering pattern or a cross-sectional transmission type electron microscope (TEM) image of a film containing the QDs. Similarly, the number average particle diameter of nanoparticles such as QDs can be measured by using, for example, a cross-sectional TEM image. Note that the number average particle diameter of nanoparticles (for example, QDs) indicates the diameter of a nanoparticle (for example, QD) at an integral value of 50% in a particle size distribution. When the number average particle diameter of nanoparticles (for example, QDs) is determined from the cross-sectional TEM image, the number average particle diameter can be determined as follows, for example. First, the area of a cross section of each nanoparticle (for example, QD) is determined from the outer shape of each of cross sections of a predetermined number (for example, 30) of adjacent nanoparticles (for example, QDs) by using, for example, TEM. Next, all of these nanoparticles (for example, QDs) are assumed to be circles, and the diameter for the area of the circle corresponding to the area of each cross section is calculated. Then, an average value of the calculated diameters is calculated.

When m1×m2+n is made equal to or more than 2, the second ligand 42 represented by the general formula (1) described above contains the coordinating functional groups at both ends, and contains an alkylene group directly bonded to the polar bonding group described above between the coordinating functional groups. Thus, a decrease in light-emission characteristics due to deactivation of the first QDs 21 can be suppressed. By setting m1×m2+n to be equal to or less than 20, when the nanoparticle is the QD and the nanoparticle layer pattern is the EML as described above, the EML in which the rate of the QDs is high, and the luminous efficiency is high can be formed. Thus, by setting m1×m2+n to be equal to or less than 20, the EML 13 in which a rate of the first QDs 21 is high and the luminous efficiency is high can be formed. In addition, by setting m1×m2+n to be equal to or less than 20, luminescence non-uniformity due to the second ligand 42 represented by the general formula (1) described above being excessively long can be suppressed.

In addition, by setting m1×m2+n to be equal to or less than 10, the bonding strength of the nanoparticles (the first QDs 21 in the present embodiment) with the second ligand 42 represented by the general formula (1) described above interposed therebetween can be increased. Thus, in this case, for example, a layered body capable of sufficiently suppressing layer peeling of the nanoparticle layer pattern (the EML 13 in the present embodiment) can be obtained. By setting m1×m2+n to be equal to or more than 3, when the nanoparticles are QDs as described above, deactivation of the QDs can be more reliably suppressed, and a decrease in light-emission characteristics due to the deactivation of the QDs can be more reliably suppressed. Accordingly, by setting m1×m2+n to be equal to or more than 3, deactivation of the first QDs 21 can be more reliably suppressed, and deterioration of light-emission characteristics due to the deactivation of the first QDs 21 can be more reliably suppressed.

In addition, when A² is a —((CH₂)ₘ₃—X²)ₘ₄-group, the ligand represented by the general formula (1) described above satisfies 2≤m1×m2+m3×m4+n≤20, and more desirably satisfies 3≤m1×m2+m3×m4+n≤10.

As described above, in the case where the distance between the nanoparticles (the first QDs 21 in the present embodiment) with the second ligand 42 interposed therebetween is too short, when the nanoparticles are QDs, the QDs may be deactivated, which may cause a decrease in luminous efficiency. By setting m1×m2+m3×m4+n to be equal to or more than 2, the second ligand 42 represented by the general formula (1) described above contains the coordinating functional groups at both ends and contains an alkylene group directly bonded to the polar bonding group described above between the coordinating functional groups at the both ends. Thus, a decrease in light-emission characteristics due to deactivation of the QDs (the first QDs 21 in the present embodiment) can be suppressed. In addition, by setting m1×m2+m3×m4+n to be equal to or less than 20, when the nanoparticle is the QD and the nanoparticle layer pattern is the EML as described above, the EML in which the rate of the QDs is high and the luminous efficiency is high can be formed. Accordingly, by setting m1×m2+m3×m4+n to be equal to or less than 20, the EML 13 in which a rate of the first QDs 21 is high and the luminous efficiency is high can be formed. In addition, by setting m1×m2+m3×m4+n to equal to or less than 20, luminescence non-uniformity caused by the second ligand 42 represented by the above-described general formula (1) being too long can be suppressed.

In addition, by setting m1×m2+m3×m4+n to be equal to or less than 10, the bonding strength of the nanoparticles (the first QDs 21 in the present embodiment) with the second ligand 42 represented by the above-described general formula (1) interposed therebetween can be increased. Thus, by setting m1×m2+m3×m4+n to be equal to or less than 10, for example, a layered body capable of sufficiently suppressing layer peeling of the nanoparticle layer pattern (the EML 13 in the present embodiment) can be obtained. In addition, by setting m1×m2+m3×m4+n to be equal to or more than 3, when the nanoparticles are QDs as described above, deactivation of the QDs can be more reliably suppressed, and a decrease in light-emission characteristics due to the deactivation of the QDs can be more reliably suppressed. Thus, by setting m1×m2+m3×m4+n to be equal to or more than 3, deactivation of the first QDs 21 can be more reliably suppressed, and deterioration of light-emission characteristics due to the deactivation of the first QDs 21 can be more reliably suppressed.

Additionally, in the ligand represented by the above-described general formula (2), as described above, Z represents a substituted or unsubstituted alkylene group having 1 to 10 carbons, or a substituted or unsubstituted unsaturated hydrocarbon group having 2 to 10 carbons. Note that the substituted or unsubstituted alkylene group and the substituted or unsubstituted unsaturated hydrocarbon group are as described above. Further, the substituents are also as described above. Thus, the ligand represented by the above-described general formula (2) may also be a bifunctional molecule containing the coordinating functional groups, which may be the same as or different from each other, at both ends of the main chain, or a polyfunctional molecule containing the coordinating functional groups at the both ends of the main chain and at a side chain.

Note that as the ligand represented by the above-described general formula (2), a ligand in which Z described above is a substituted or unsubstituted alkylene group having 4 to 10 carbons or a substituted or unsubstituted unsaturated hydrocarbon group having 4 to 10 carbons is more preferable.

When the number of carbons in Z described above exceeds 10, it becomes difficult to dissolve the ligand represented by the above-described general formula (2) in, for example, a polar solvent in forming the nanoparticle layer pattern (the EML 13 in the present embodiment). In addition, when the number of carbons in Z described above is equal to or more than 4, the distance between the nanoparticles to which the ligand represented by the above-described general formula (2) is coordinated is increased, and thus, when the nanoparticles are, for example, QDs as described above, the luminous efficiency can be improved.

The second ligand 42 described above is not particularly limited as long as the second ligand 42 is a ligand having at least one kind of at least two coordinating functional groups as described above, and specific examples thereof include 1,2-ethanedithiol, 1,2-propanedithiol, 1,3-propanedithiol, 1,2-butanedithiol, 1,3-butanedithiol, 1,4-butanedithiol, 2,3-butanedithiol, 1,6-hexanedithiol, 1,8-octanedithiol, 1,2-propanediamine, 1,3-propanediamine, 1,4-butanediamine, 3-amino-5-mercapto-1,2,4-triazole, 2-aminobenzenethiol, toluene-3,4-dithiol, dithioerythritol, dihydrolipoic acid, thiolactic acid, 3-mercaptopropionic acid, 1-amino-3,6,9,12,15,18-hexaoxaheneicosan-21-oic acid, 2-[2-(2-aminoethoxy)ethoxy]acetic acid, 2,2′-(ethylenedioxy)diethanethiol, 2,2′-oxydiethanethiol, (12-phosphonododecyl)phosphonic acid, 11-mercaptoundecylphosphonic acid, 11-phosphonoundecanoic acid, and ethylene glycol bis(3-mercaptopropionate). A single type of these ligands may be used alone, or two or more types may be mixed and used, as appropriate.

Among these exemplified ligands, 2,2′-(ethylenedioxy)diethanethiol is particularly preferable as the second ligand 42 described above.

By using 2,2′-(ethylenedioxy)diethanethiol as the second ligand 42 described above, the EML 13 in which a rate of the first QDs 21 is high and the luminous efficiency is high can be formed. In addition, by using 2,2′-(ethylenedioxy)diethanethiol as the second ligand 42 described above, a decrease in light-emission characteristics due to deactivation of the first QDs 21 can be suppressed, and luminescence non-uniformity due to the second ligand 42 becoming too long can be suppressed. In addition, the bonding strength of the first QDs 21 with the above-described second ligand 42 interposed therebetween can be increased, and the layer peeling of the EML 13 described above can be sufficiently suppressed.

A content ratio of the first QD 21 and the second ligand 42 in the EML 13 (the first QD 21:the second ligand 42) is not particularly limited, but is preferably within a range from 2:0.25 to 2:6, and more preferably within a range from 2:1 to 2:4 in a weight ratio. Thus, a plurality of first QDs 21 are bonded to each other with the second ligand 42 interposed therebetween, and the EML 13 in which liquid resistance to polar solvents and non-polar solvents is high and deterioration in patterning is suppressed can be formed. Additionally, in general, most of the molecular skeleton of a ligand is composed of an organic matter, and thus, the ligand often exhibits insulating properties. Because of this, from the viewpoint of injection of carriers in the light-emission characteristics of the light-emitting element 1 described above, the EML 13 preferably does not contain an excessive amount of ligands. Accordingly, the content ratio described above is desirably within the range described above.

On the other hand, the first ligand 22 is a surface modifier that modifies the surface of the first QD 21 by coordinating the first ligand 22 to the surface of the first QD 21 with the first QD 21 serving as a receptor. As the first ligand 22, a monofunctional ligand containing one coordinating functional group (adsorbing group) for coordination (adsorption) to the first QD 21 is used. The first ligand 22 is not particularly limited as long as the first ligand 22 is the monofunctional ligand, and may be, for example, a monomer or an oligomer.

For example, commercially available QD colloidal solutions typically contain ligands. By coordinating the ligands on the surfaces of the QDs, mutual aggregation of the QDs can be suppressed.

Thus, a commercially available QD colloidal solution may be used as the colloidal solution 24, and the first ligand 22 may be a ligand contained in the commercially available QD colloidal solution. Note that for long-term storage of the QD colloidal solution, the use of an oligomer or the like as a ligand may cause higher stability. However, it is easier to exchange the first ligand 22 with the second ligand 42 when the first ligand 22 is also a monomer. Accordingly, the first ligand 22 described above may be a monomer containing one coordinating functional group allowing coordination to the first QD 21.

As described above, examples of the coordinating functional group described above include at least one kind of functional group selected from the group consisting of a thiol group, an amino group, a carboxyl group, a phosphone group, a phosphine group, and a phosphine oxide group.

Examples of the ligand containing one thiol group as the coordinating functional group described above include thiol-based ligands such as octadecanethiol, hexanedecanethiol, tetradecanethiol, dodecanethiol, decanethiol, and octanethiol.

Examples of the ligand containing one amino group as the coordinating functional group described above include primary amine-based ligands such as oleylamine, stearylamine (octadecylamine), dodecylamine (laurylamine), decylamine, and octylamine.

Examples of the ligand containing one carboxyl group as the coordinating functional group described above include fatty acid-based ligands such as oleic acid, stearic acid, palmitic acid, myristic acid, lauryl (dodecanoic) acid, decanoic acid, and octanoic acid.

Examples of the ligand containing one phosphone group as the coordinating functional group described above include phosphonic acid-based ligands such as hexadecylphosphonic acid and hexylphosphonic acid.

Examples of the ligand containing one phosphine group as the coordinating functional group described above include phosphine-based ligands such as trioctylphosphine, triphenylphosphine, and tributylphosphine.

Examples of the ligand containing one phosphine oxide group as the coordinating functional group described above include phosphine oxide-based ligands such as trioctylphosphine oxide, triphenylphosphine oxide, and tributylphosphine oxide.

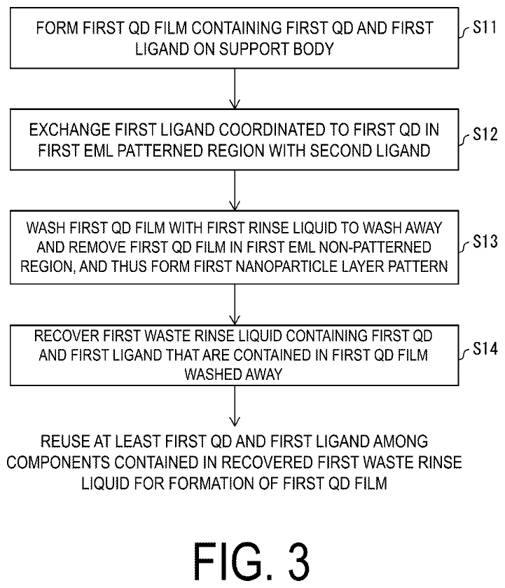

A forming process of the EML 13 described above will be described below in more detail with reference to FIG. 3 to FIG. 5.

The EML 13 is formed by applying a colloidal solution, in which QDs coordinated with ligands are dissolved in a solvent, onto an underlayer thereof (on the HTL 12 in the example illustrated in FIG. 1) and performing patterning by a solution method. Note that in the disclosure, dissolving QDs in a solvent means dispersing QDs in a solvent until the QDs become colloidal. In the present embodiment, as described above, the first QD 21 is used as the QD described above.

As described above, in the present embodiment, the method for patterning a nanoparticle film according to the present embodiment is adopted to the formation of the EML 13.

FIG. 3 is a flowchart illustrating an example of an EML forming process (step S3) using the method for patterning a nanoparticle film according to the present embodiment. FIG. 4 is cross-sectional views illustrating a part of the EML forming process illustrated in FIG. 3 in order of the process.

The EML forming process (step S3) according to the present embodiment includes, for example, a first QD film forming process (step S11, first nanoparticle film forming process), a first ligand exchanging process (step S12), a first washing process (step S13), and a first waste rinse liquid recovering process (step S14). More details will be described below.

In the method for patterning a nanoparticle film according to the present embodiment, first, as the first nanoparticle film forming process, a nanoparticle film (first nanoparticle film) to be patterned is formed on an underlayer serving as a support body. Thus, in the EML forming process (step S3), first, as indicated by S11 in FIG. 3, a first QD film is formed as the first nanoparticle film on the HTL 12 as the support body (strictly, on a substrate on which the HTL 12 is formed) (step S11, the first QD film forming process).

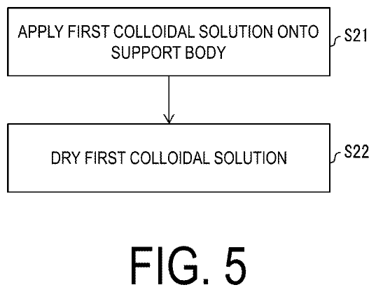

FIG. 5 is a flowchart illustrating an example of the first QD film forming process (step S11) illustrated by S11 in FIG. 3.

As illustrated in FIG. 5, the first QD film forming process (step S11) includes, for example, a first colloidal solution applying process (step S21) and a first colloidal solution drying process (step S22).

In the first QD film forming process (step S11), as illustrated by S11-1 in FIG. 4 and S21 in FIG. 5, first, the colloidal solution 24 as a first colloidal solution is applied onto the HTL 12 as the support body (step S21, the first colloidal solution applying process).

Next, as indicated by S22 in FIG. 5, the colloidal solution 24 applied onto the HTL 12 described above is dried (step S22, the first colloidal solution drying process). Thus, as indicated by S11 in FIG. 3 and by S11-2 in FIG. 4, the first QD film 31 containing the first QD 21 and the first ligand 22 is formed on the HTL 12 described above as a first nanoparticle film.

Note that the colloidal solution 24 may be dried by heating and drying such as baking. A drying temperature (for example, a baking temperature) may be appropriately set according to a type of the solvent 23 so that an unnecessary solvent 23 contained in the colloidal solution 24 can be removed. Because of this, the drying temperature is not particularly limited, but is preferably within a range from 60 to 120° C., for example. Thus, the unnecessary solvent 23 contained in the colloidal solution 24 can be removed without causing thermal damage to the first QD 21. Note that a drying time period may be appropriately set according to the drying temperature so that the unnecessary solvent 23 contained in the colloidal solution 24 can be removed, and is not particularly limited.

Next, as indicated by S12 in FIG. 3, the first ligand 22 coordinated to the first QD 21 in a first EML patterned region 32 (first nanoparticle layer patterned region) corresponding to a part of the first QD film 31 is exchanged with the second ligand 42 (step S12, the first ligand exchanging process).

The first EML patterned region 32 is a region for forming an EML pattern (a first EML pattern) containing the first QD 21 and the second ligand 42. In the present embodiment, the first EML patterned region 32 is a region for patterning the EML 13. In order to exchange the first ligand 22 coordinated to the first QD 21 in the first EML patterned region 32 with the second ligand 42, as indicated by S12-1 in FIG. 4, the first solution 41 containing the second ligand 42 and the solvent 43 may be supplied to the first EML patterned region 32 to be in contact with the first EML patterned region 32. The first solution 41 is a second ligand supplying solution for supplying the second ligand 42 to the first EML patterned region 32.

In order to exchange the first ligand 22 coordinated to the first QD 21 in the first EML patterned region 32 with the second ligand 42, it is only required to bring the first solution 41 into contact with the first EML patterned region 32 as described above, and it is not particularly required to perform heating. Further, in view of the layer thickness of a typical EML, the first solution 41 permeates into the first EML patterned region 32 immediately after the first solution 41 is supplied to the first EML patterned region 32. Thus, management and control of a time period to be required for ligand exchange are not particularly required. Note that, heating may be performed as necessary, and a holding time period for the permeation of the first solution 41 may be provided.

Examples of a method for supplying the first solution 41 to the first EML patterned region 32 to bring the first solution 41 into contact with the first EML patterned region 32 include a method for sprinkling the first solution 41 on the first EML patterned region 32. Note that the first solution 41 may be spread on the first EML patterned region 32 as mist by spraying, or as drops by dropping, for example. For sprinkling (supplying) the first solution 41, for example, an ink-jet method may be used, or a mist spraying device may be used. Further, in order to uniformly apply the first solution 41 to the first EML patterned region 32, the first solution 41 may be supplied (for example, spread) onto the first EML patterned region 32, and then, the supplied first solution 41 may be applied to the surface of the first EML patterned region 32 by spin coating.

At this time, as indicated by S12-1 in FIG. 4, a mask M1 including an opening MA1 that exposes the first EML patterned region 32 of the first QD film 31 may be used. As described above, the mask M1 is disposed on the first QD film 31, and the first solution 41 is brought into contact with the first EML patterned region 32 through the opening MA1 of the mask M1, whereby the region in which the first ligand 22 is exchanged can be easily controlled with high accuracy.

When the first solution 41 containing the second ligand 42 is brought into contact with the first EML patterned region 32, the first ligand 22 coordinated to the first QD 21 of the first EML patterned region 32 is exchanged with the second ligand 42. Thus, the first ligand 22 coordinated to the first QD 21 in the first EML patterned region 32 can be exchanged with the second ligand 42 in the entire first EML patterned region 32 by permeating the first solution 41 into the first EML patterned region 32.

As described above, the second ligand 42 contains at least one type of at least two coordinating functional groups allowing coordination to the first QD 21. Thus, as indicated by S12-2 in FIG. 4, when the first ligand 22 coordinated to the first QD 21 in the first EML patterned region 32 is exchanged with the second ligand 42, the second ligand 42 connects the plurality of first QDs 21 in the first EML patterned region 32 to each other. As a result, the first QD film 31 in the first EML patterned region 32 is cured and insolubilized in a rinse liquid.

Then, as necessary, the first QD film 31 described above is heated, dried and the like to complete the ligand exchange described above and to remove an unnecessary solvent 43 contained in the first QD film 31 described above (the first nanoparticle film drying process). Next, as indicated by the S13 in FIG. 3, the first QD film 31 described above is washed with the rinse liquid 44 (first rinse liquid, first washing liquid). Thus, the first QD film 31 in a region (first EML non-patterned region 33) other than the first EML patterned region 32 is removed (step S13, the first washing process). After the washing with the rinse liquid 44 is performed as described above, the rinse liquid 44 is volatilized to pattern the EML 13 containing the first QD 21 and the second ligand 42 as the first nanoparticle layer pattern according to the present embodiment as indicated by S13 in FIG. 4. Note that although there is a possibility that the first ligand 22 is slightly contained in the EML 13, it is sufficient that the pattern is formed without removing the EML 13 by the rinse liquid 44.

The washing method described above is not particularly limited, and known various methods may be employed. For example, as described in Examples to be described later, after a sufficient amount of the rinse liquid 44 is supplied and applied to the first QD film 31, the first QD film 31 may be heated and dried.

Note that in the present embodiment, thereafter, as necessary, as indicated by S14 in FIG. 3 and S13 in FIG. 4, a waste rinse liquid 44′ (first waste rinse liquid, first waste washing liquid) containing the first QD 21 and the first ligand 22 that are contained in the first QD film 31 washed away in step S13 described above, and the rinse liquid 44 used for the washing is recovered (step S14, the first waste rinse liquid recovering process).

At least the first QD 21 and the first ligand 22 among the components (to be specific, the first QD 21, the first ligand 22, and the rinse liquid 44 used for the washing) contained in the waste rinse liquid 44′ recovered in step S14 can be reused for forming the first QD film 31 in step S11 in manufacturing for another light-emitting element 1.

The solubility of the ligand alone is slightly different from the solubility of the ligand and the first QD 21 in a state where the ligand is coordinated to the first QD 21. Thus, the solvent 23 in the colloidal solution 24 is not particularly limited as long as the solvent 23 can dissolve the first QD 21 and the first ligand 22 in a state of the first QD 21 alone and the first ligand 22 alone, and in a state where the first ligand 22 is coordinated to the first QD 21. On the other hand, when a solvent in which the first QD 21 in the first QD film 31 is dissolved is used as the solvent 43 in the first solution 41, not only ligand exchange but also dissolution of the first QD film 31 occur. Thus, the solvent 43 is not particularly limited as long as the solvent 43 does not dissolve the first QD 21 alone and the first ligand 22 alone, and the first QD 21 and the first ligand 22 in a state where the first ligand 22 is coordinated to the first QD 21, and can dissolve the second ligand 42. In addition, when the second ligand 42 is coordinated to the first QD 21 by the ligand exchange, the first QD 21 to which the second ligand 42 is coordinated is insolubilized and is not dissolved in any solvents. Accordingly, a solvent to be used as the rinse liquid 44 is not particularly limited as long as the solvent dissolves the first ligand 22 coordinated to the first QD 21 and dissolves the excessive second ligand 42 and first ligand 22 that are not coordinated to the first QD 21.

As the solvent 43, a polar solvent is generally used regardless of whether the second ligand 42 is a polar molecule containing the above-described polar bonding groups or a non-polar molecule not containing the above-described polar bonding groups. In addition, nanoparticles such as QDs are usually easily degraded by water. Then, the first QD 21 alone and the first ligand 22 alone, and the first QD 21 and the first ligand 22 in a state where the first ligand 22 is coordinated to the first QD 21 are dissolved in a non-polar solvent (apolar solvent). Thus, a non-polar solvent (apolar solvent) is generally used as the solvent 23 and the rinse liquid 44.

However, semiconductor nanoparticles such as QDs or inorganic oxide nanoparticles such as ZnO are dissolved (dispersed) in a highly polar solvent such as water or ethanol unless a special treatment is performed. Thus, as described in a modified example, which will be described later, in a case where the second ligand 42 is subjected to ligand exchange (ligand addition) to the untreated first nanoparticle such as a case where the first nanoparticle is a nanoparticle having carrier transport properties such as ZnO, it is necessary to use a polar solvent as the solvent 23 and a non-polar solvent as the solvent 43 so as not to dissolve the first nanoparticle film (for example, a ZnO film). Additionally, the first ligand 22, which is a monofunctional ligand, is dissolved (dispersed) in a solvent having a polarity having the magnitude corresponding to the magnitude of a polarity that a terminal group of the ligand has. Thus, even when a ligand containing a polar bonding group is coordinated to the first QD 21 as the first ligand 22, it is necessary to use a polar solvent as the solvent 23 and use a non-polar solvent as the solvent 43 so that the first QD film 31 serving as the first nanoparticle film is not dissolved. When a polar solvent is used as the solvent 23 and a non-polar solvent is used as the solvent 43 as described above, a polar solvent is used as the rinse liquid 44. However, as described above, since nanoparticles such as QDs are easily deteriorated by water, when a polar solvent is used as the solvent 23 and the rinse liquid 44, a solvent other than water is desirably used.

As the non-polar solvent, for example, a solvent having a Hildebrand solubility parameter (δ value) being equal to or less than 9.3 is preferably used, and a solvent having the δ value being equal to or more than 7.3 and equal to or less than 9.3 is more preferably used. Additionally, as the non-polar solvent, for example, a solvent having a relative dielectric constant (εᵣ value) being equal to or less than 6.02, which is measured at around 20° C. to 25° C., is preferably used, and a solvent having the above-described εᵣ value being equal to or more than 1.89 and equal to or less than 6.02 is more preferably used. These non-polar solvents are good solvents for the first QD 21 to which the first ligand 22 is coordinated, and can dissolve 50% or more of the first QDs 21 to which the first ligands 22 are coordinated. In addition, the non-polar solvents described above do not degrade the nanoparticles such as QDs (the first QDs 21 in the present embodiment), and do not dissolve the first QDs 21 to which the second ligands 42 are coordinated. Thus, the solvent described above is preferably used as the non-polar solvent described above.

The non-polar solvent described above is not particularly limited, but examples of the non-polar solvent include at least one type of solvent selected from the group consisting of toluene, hexane, octane, and chlorobenzene. Toluene, hexane, and octane are non-polar solvents having the above-described δ value being equal to or more than 7.3 and equal to or less than 9.3 and the above-described εᵣ value being equal to or more than 1.89 and equal to or less than 6.02, and have a particularly high solubility of the first QDs 21 to which the first ligands 22 are coordinated, for example, and are easily available. Chlorobenzene is a non-polar solvent in which the εᵣ value described above is equal to or less than 6.02. For example, chlorobenzene has a particularly high solubility of the first QDs 21 to which the first ligands 22 are coordinated and is easily available. Accordingly, the solvent described above is preferably used as the non-polar solvent described above.

On the other hand, as the polar solvent described above, for example, a solvent having the above-described δ value being more than 9.3 is preferably used, and a solvent having the above-described δ value being more than 9.3 and equal to or less than 12.3 is more preferably used. Additionally, the δ value of the polar solvent described above is more preferably equal to or more than 10. Thus, the polar solvent is even more preferably a solvent having the above-described δ value being equal to or more than 10 and equal to or less than 12.3. In addition, the polar solvent is preferably, for example, a solvent having the above-described εᵣ value being more than 6.02, and more preferably a solvent having the above-described gr value being more than 6.02 and equal to or less than 46.7.

The polar solvent is not particularly limited, and examples thereof include at least one kind of solvent selected from the group consisting of propylene glycol monomethyl ether acetate (PGMEA), methanol, ethanol, acetonitrile, and ethylene glycol. At least one kind of solvent selected from the group consisting of PGMEA, methanol, ethanol, acetonitrile, and ethylene glycol is a polar solvent having a solubility parameter being equal to or more than 10, is easily available, and has a small number of molecules. Thus, not only when the second ligand 42 described above is a polar molecule but also when the second ligand 42 described above is a non-polar molecule, the second ligand 42 described above can be uniformly dissolved.

Note that a concentration of the first QDs 21, a concentration of the first ligands 22, and a concentration of the first ligands 22 with respect to the first QDs 21 in the colloidal solution 24 described above may be set in a way similar to that in the prior art, and are not particularly limited as long as the colloidal solution 24 has a concentration or viscosity that is coatable. For example, a concentration of QDs in a case of using a spin coating method is generally set to about 5 to 20 mg/mL in order to obtain a practical QD film thickness. However, the above-described example is only an example, and an optimum concentration varies depending on a film formation method.

Further, a concentration of the second ligands 42 contained in the first solution 41 described above is not particularly limited, but is desirably within a range from 0.01 mol/L to 2.0 mol/L.

In order to perform the ligand exchange, the first solution 41 described above needs to dissolve (disperse) the first ligand 22 coordinated to the first QD 21 described above before the ligand exchange. Thus, the concentration of the second ligands 42 described above is preferably within the above range in view of the balance between the supply of the second ligand 42 described above and the dissolution of the first ligand 22 described above into the first solution 41 described above.

Moreover, as described above, a content ratio of the first QD 21 and the second ligand 42 in the EML 13 (the first QD 21:the second ligand 42) is preferably within a range from 2:0.25 to 2:6, and more preferably within a range from 2:1 to 2:4 in a weight ratio. A supply amount of the second ligands 42 varies depending on, for example, a type and a film thickness of the first nanoparticle film to which the second ligand 42 is supplied, a method for applying the second ligand 42, a size of the light-emitting region, and the like. However, since the amount of the second ligands 42 to be supplied per one first QD 21 is sufficient regardless of the above-described conditions, the amount of the second ligands 42 actually coordinated to the first QD 21 tends to depend on the concentration of the second ligands 42 contained in the first solution 41. Then, in step S13, the excessive second ligand 42 not coordinated to the first QD 21 is removed with the rinse liquid 44. In addition, in step S12, the excessive amount of the second ligands 42, compared to the above-described content ratio of the first QD 21 and the second ligand 42 in the EML 13, are supplied to the first QDs 21 so that the content ratio of the first QD 21 and the second ligand 42 in the EML 13 finally falls within the above-described range by removing the excessive second ligand 42 in step S13. Thus, when the concentration of the second ligands 42 in the first solution 41 is set within the above-described range, the content ratio of the second ligand 42 and the first QD 21 within the above-described desirable range can be obtained in the EML 13 to be finally formed by supplying the first solution 41 so that the first solution 41 permeates into the entire first nanoparticle film in the first EML patterned region 32 where the ligand exchange is performed. As a result, the plurality of first QDs 21 is bonded to each other with the second ligand 42 interposed therebetween, and the EML 13 in which deterioration in patterning is suppressed and in which a decrease in carrier injection efficiency is suppressed, the EML 13 having high liquid resistance to polar solvents and non-polar solvents, can be formed.

Additionally, the viscosity of the first solution 41 described above can be appropriately adjusted within a desired range by adjusting the temperature, pressure, and the like in applying the first solution 41 described above. Thus, the viscosity of the first solution 41 described above is not particularly limited, but is desirably within a range from 0.5 mPa·s to 500 mPa·s. Accordingly, it is possible to reduce non-uniform contact between the first QD film 31 and the first solution 41 and non-uniform permeation of the first solution 41 into the first QD film 31 in the first EML patterned region 32 of the first QD film 31, and to reduce non-uniform coating of the first solution 41 during drying. As a result, the layer thickness of the EML 13 (first nanoparticle layer pattern) to be finally obtained can be easily adjusted.

Moreover, the viscosity of the first solution 41 is more preferably within a range from 1 mPa·s to 100 mPa·s. Thus, it is possible to further reduce non-uniform contact between the first QD film 31 and the first solution 41 and non-uniform permeation of the first solution 41 into the first QD film 31 in the first EML patterned region 32 of the first QD film 31, and to further reduce non-uniform coating of the first solution 41 during drying. As a result, the layer thickness of the EML 13 (first nanoparticle layer pattern) to be finally obtained can be more easily adjusted.

Note that the viscosity can be measured by using a conventionally known rotational viscometer, B-type viscometer, or the like. In the present embodiment, values measured in accordance with “JIS 8803Z:2011 Method for measuring viscosity of liquid” by using a vibration type viscometer VM-10A-L manufactured by CBC Materials Co., Ltd. will be described.

In addition, in step S12 (the first ligand exchanging process), a droplet diameter of the first solution 41 spread on the first EML patterned region 32 of the first QD film 31 is preferably equal to or more than 10 μm and equal to or less than 1 mm. Further, according to this, in a case where, for example, a spray (mist spraying device), an ink jet, or the like is used for the spread of the first solution 41, pixels with high definition can be formed within a range in which the spray or the ink jet can be used.

As described above, the method for patterning a nanoparticle film according to the present embodiment includes the first QD film forming process (first nanoparticle film forming process) of forming the first QD film 31 (first nanoparticle film) on the support body, the first QD film 31 containing the first QD 21 serving as the first nanoparticle and the first ligand 22, the first ligand exchanging process of bringing the first solution 41 containing the second ligand 42 into contact with the first EML patterned region 32 that is a part of the first QD film 31 (first nanoparticle layer patterned region), to exchange the first ligand 22 coordinated to the first QD 21 in the first EML patterned region 32 with the second ligand 42, and the first washing process of washing the first QD film 31 with the rinse liquid 44 (first washing liquid), to wash away and remove the first QD film 31 in the first EML non-patterned region 33 other than the first EML patterned region 32, the first EML non-patterned region 33 not being brought into contact with the first solution 41, thereby forming the EML 13 (first nanoparticle layer pattern).

As described above, when the first ligand 22 coordinated to the first QD 21 is exchanged with the second ligand 42, the first QD 21 to which the second ligand 42 is coordinated is cured and insolubilized in the rinse liquid 44. Due to this, when the first QD film 31 is washed with the rinse liquid 44, the first QD film 31 in the first EML non-patterned region 33 in which the first ligand 22 has not been exchanged because of no contact with the first solution 41 is washed away and removed by the rinse liquid 44. Thus, according to the above-described method, the method for patterning a nanoparticle film that does not require irradiation with ultraviolet light and that can suppress deterioration of the EML 13 to be formed can be provided.

Note that the coordination of the second ligand 42 to the first QD 21 can be checked by the fact that the first QD 21 to which the second ligand 42 is coordinated is not dissolved in the rinse liquid 44.

Further, depending on the ligand to be coordinated, the presence or absence of the coordination can be checked by, for example, measurement using Fourier transform infrared spectroscopy (FT-IR) (hereinafter, referred to as “FT-IR measurement”). For example, when the ligand to be coordinated to the first QD 21 contains a —C(═O)OH group as a coordinating functional group to be coordinated to the first QD 21, or when a coordinating functional group coordinated to the first QD 21 contains a —P(═O) group, vibrations observed in the FT-IR measurement slightly differ between an uncoordinated state and a coordinated state, and the detection peak shifts. Thus, this enables the coordination of the first ligand 22 or the second ligand 42 to the first QD 21 to be checked.

In addition, after the ligand exchange, a peak of the first ligand 22 before the exchange disappears, and due to the replacement with only the second ligand 42 after the exchange, the fact that the second ligand 42 is coordinated to the first QD 21 can also be checked.

Further, when at least one of the first ligand 22 and the second ligand 42 contains a functional group exhibiting a specific peak in addition to the coordinating functional groups to be coordinated to the first QD 21, the coordination can be checked by a detected amount thereof. Examples of such a functional group include an ether group, an ester group, and a C═C bond of oleic acid. In particular, when a specific peak that has existed before the ligand exchange disappears after the ligand exchange, or when a new specific peak is detected after the ligand exchange, the fact that the ligand exchange has been performed can be checked.

Hereafter, the effects described above will be described in more detail through Examples and Comparative Example.

### Example 1

First, a red QD including a core that contains CdSe and that has a particle diameter of 1 nm and a shell that contains ZnSe and that has a light emission peak wavelength of 630 nm was synthesized by using a known method. Next, as the first colloidal solution, a colloidal solution containing the above-described red QDs as the first nanoparticles, octanethiol (CH₃(CH₂)₇SH) as the first ligand, and toluene as the first solvent at rates of a ligand concentration of 20 wt % and a QD concentration of 20 mg/mL was prepared. Subsequently, the colloidal solution described above was applied onto a glass substrate as a support body for measuring optical characteristics by spin coating at 2000 rpm, and then, baking was performed at 100° C. to remove the unnecessary solvent and to perform drying. As a result, the first QD film containing the above-described red QD and octanethiol was formed on the glass substrate described above as the first nanoparticle film. The first QD film described above had a film thickness of 60 to 65 nm.

Next, as the first solution containing the second ligand, an acetonitrile solution containing 2,2′-(ethylenedioxy)diethanethiol(HSCH₂CH₂OCH₂CH₂OCH₂CH₂SH) as the second ligand and having a concentration of 0.1 mol/L was prepared. Next, the first solution described above of 200 μL was spread on the first QD film described above, and after 10 seconds elapsed, the spread first solution described above was applied by spin coating at 2000 rpm. Next, the first QD film described above was baked at 100° C. for 10 minutes to remove acetonitrile contained in the first QD film. Next, after the film thickness of the first QD film described above was measured, a sufficient amount of toluene as a rinse liquid was spread onto the first QD film described above. Then, after 10 seconds elapsed from the spread of toluene, the spread toluene described above was applied by spin coating at 2000 rpm, and then, heating was performed at 100° C. to wash the first QD film described above. Here, note that the sufficient amount means an amount sufficient for the substrate size of the support body to be used. Note that in the present embodiment, as an example, a glass substrate of 25 mm×25 mm×0.7 mm was used as the glass substrate serving as the support body described above in Examples and Comparative Example. According to this, the rinse liquid of 200 μL was used as the sufficient amount of the rinse liquid.

Thereafter, the film thickness of the first QD film described above and an absorbance and a light emission intensity with respect to light having a wavelength of 450 nm were measured.

Note that the film thickness of the first QD film described above was measured with a film thickness step profiler. Moreover, the absorbance of the first QD film described above with respect to light having a wavelength of 450 nm was measured with a UV-Vis (ultraviolet-visible) spectrophotometer. The light emission intensity of the first QD film described above with respect to light having the wavelength of 450 nm was measured by a photoluminescence (PL) lifetime measuring device.

Moreover, the first QD film described above was further washed and dried with a sufficient amount of toluene in a way similar to that as described above, and the film thickness of the first QD film and the absorbance and the light emission intensity with respect to light having the wavelength of 450 nm were measured again.

### Example 2

In Example 1, the same operations and measurements as those in Example 1 were carried out except that 1,2-ethanedithiol(HSCH₂CH₂SH) was used as the second ligand instead of 2,2′-(ethylenedioxy)diethanethiol.

### Comparative Example 1

The same operations and measurements as those in Example 1 were performed except that the ligand exchange of the first ligand described above was not performed. To be more specific, the colloidal solution prepared in Example 1 was applied onto a glass substrate as a support body by spin coating at 2000 rpm, and then, baking was performed at 100° C. to remove the unnecessary solvent and to perform drying. Thus, as the first nanoparticle film, the first QD film containing the red QD described above and octanethiol as the first nanoparticle film was formed as the first nanoparticle film on the glass substrate described above. The first QD film described above had a film thickness of 60 to 65 nm. Next, a sufficient amount of toluene was spread onto the first QD film as the rinse liquid, and after 10 seconds elapsed, the spread toluene was applied by spin coating at 2000 rpm, and then, heating is performed at 100° C. to wash the first QD film. Thereafter, the film thickness of the first QD film described above and an absorbance and a light emission intensity with respect to light having a wavelength of 450 nm were measured. Next, the first QD film was further washed and dried with a sufficient amount of toluene in a way similar to that described above, and the film thickness of the first QD film and the absorbance and the light emission intensity of light having the wavelength of 450 nm were measured again.

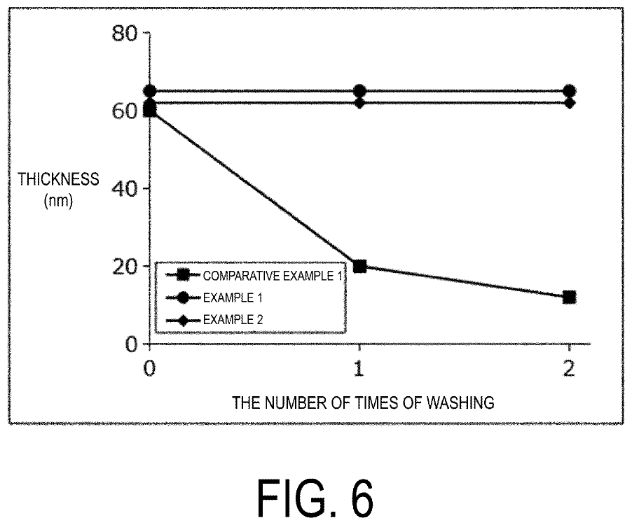

FIG. 6 is a graph illustrating a relationship between the film thickness of the first QD film after the washing described above and the number of times of washing in each of Examples 1 and 2 and Comparative Example 1.

As can be seen from Comparative Example 1 illustrated in FIG. 6, the first QD film using the first ligand containing only one coordinating functional group to be coordinated to the first QD as the ligand has low liquid resistance to toluene (a rinse liquid), which is a non-polar solvent, and the film thickness thereof decreases every time washing is performed. On the other hand, as can be seen from Examples 1 and 2 illustrated in FIG. 6, the first QD film using the second ligand containing a plurality of coordinating functional groups to be coordinated to the first QD as the ligand has high liquid resistance to toluene (a rinse liquid), which is a non-polar solvent, and the film thickness thereof does not change by washing. From this, it is understood that by exchanging the first ligand of the first QD film with the second ligand, the first QD film at a portion where the ligand exchange is not performed can be washed and removed by using the rinse liquid described above. In addition, it is found that the first QD film at a portion subjected to the ligand exchange is insolubilized in the rinse liquid, so that the first QD film at the portion subjected to the ligand exchange can remain even after the washing with the rinse liquid. Thus, according to the present embodiment, it is found that the first QD film can be patterned without requiring irradiation of ultraviolet light, and deterioration of the QD layer pattern due to patterning can be suppressed.

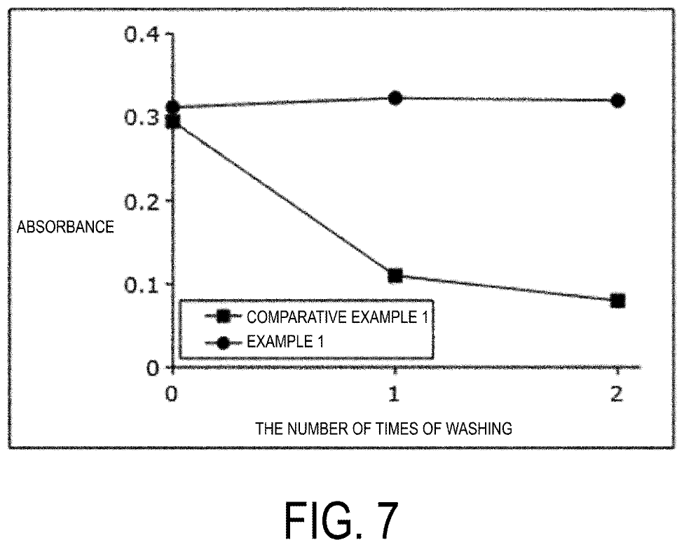

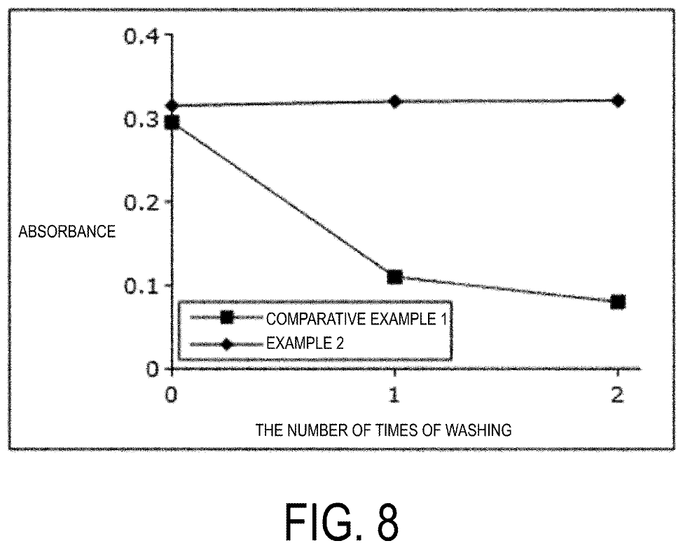

Additionally, FIG. 7 is a graph illustrating a relationship between the number of times of washing and an absorbance of the first QD film after the washing described above with respect to light having the wavelength of 450 nm in each of Example 1 and Comparative Example 1 described above. Further, FIG. 8 is a graph illustrating a relationship between the number of times of washing and an absorbance of the first QD film after the washing described above with respect to light having the wavelength of 450 nm in each of Example 2 and Comparative Example 1 described above.

As can be seen from the results illustrated in FIG. 7 and FIG. 8, the first QD film of Comparative Example 1 described above has low liquid resistance to the rinse liquid, and the absorbance decreases by the washing. On the other hand, in each of Examples 1 and 2 described above, a decrease in absorbance due to the washing is not observed. Thus, according to the present embodiment, it is found that deterioration of the EML to be formed as the nanoparticle layer pattern due to the washing accompanying patterning can be suppressed, and a light-emitting element having excellent light-emission characteristics can be manufactured.

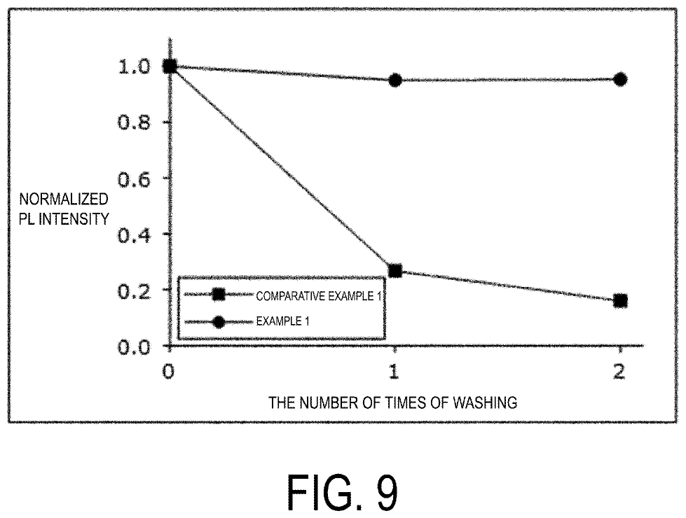

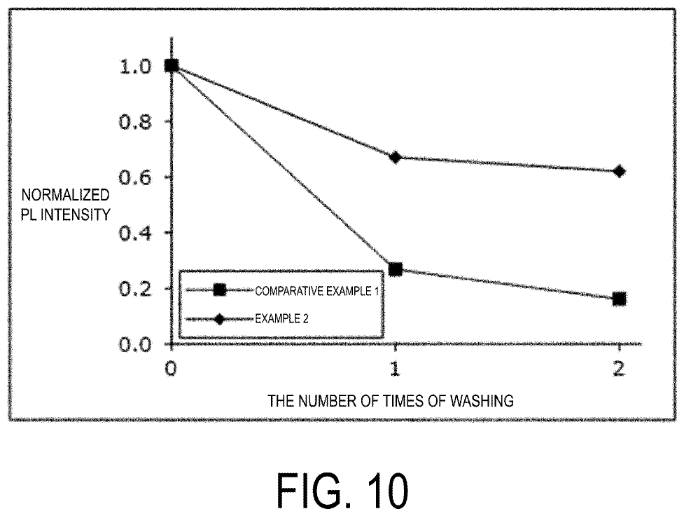

FIG. 9 is a graph illustrating a relationship between a light emission intensity of the first QD film after the washing described above with respect to light having the wavelength of 450 nm and the number of times of washing in each of Example 1 and Comparative Example 1 described above. FIG. 10 is a graph illustrating a relationship between a light emission intensity of the first QD film after the washing described above with respect to light having the wavelength of 450 nm and the number of times of washing in each of Example 2 and Comparative Example 1 described above. Note that in each of FIG. 9 and FIG. 10, a photoluminescence (PL) intensity obtained by normalization with a PL intensity of the first QD film before the washing defined as 100% (a PL intensity=1.0) is illustrated as a light emission intensity.

As illustrated in each of FIG. 9 and FIG. 10, according to Example 1 and Example 2, it is found that a light-emitting element having a higher light emission intensity than that of Comparative Example 1 can be manufactured. Thus, according to the present embodiment, it is found that deterioration of the EML to be formed as the nanoparticle layer pattern due to the washing accompanying patterning can be suppressed, and a light-emitting element having excellent light-emission characteristics can be manufactured.

Note that there was no large difference in absorbance between Example 1 and Example 2 as illustrated in FIG. 7 and FIG. 8, but a decrease in light emission intensity due to the washing was observed in Example 2 as illustrated in FIG. 10 although the decrease was not as large as that in Comparative Example 1. Generally, a light emission intensity is proportional to the product of an absorbance and a luminous efficiency. As described above, the difference between Example 1 and Example 2 is only the types of the second ligand. The second ligand of Example 1 and the second ligand of Example 2 are different from each other in length between the thiol groups that are the coordinating functional groups provided at the ends of the main chains. This suggests that the distance between the adjacent QDs to each other was more appropriately maintained in Example 1, and the distance between the adjacent QDs to each other was short and the interaction between the QDs occurred in Example 2, so that the luminous efficiency was reduced.

### First Modified Example

As described above, in the present embodiment, the case where the nanoparticle film is the QD film and the EML (QD light-emitting layer) is patterned as an example of the method for patterning a nanoparticle film has been exemplified and described. However, the disclosure is not limited thereto. The nanoparticle film may be made of, for example, a nanoparticle having carrier transport properties such as ZnO as described above, and the nanoparticle layer pattern may be a carrier transport layer such as the HTL 12 or the ETL 14, or a carrier injection layer such as an HIL or an EIL. In any case, a carrier transport layer or a carrier injection layer including a desired pattern can be formed by patterning a film containing a nanoparticle having carrier transport properties by using the method for patterning a nanoparticle film according to the disclosure. Note that examples of the nanoparticle having the carrier transport properties include the inorganic nanoparticles having the hole transport properties, which have been exemplified as the hole transport materials, or the inorganic nanoparticles having the electron transport properties, which have been exemplified as the electron transport materials.

Note that when the nanoparticle according to the disclosure is a nanoparticle having carrier transport properties, the number average particle diameter (size) of the nanoparticles is, for example, within the range from 1 to 15 nm, and the number of overlapping layers of the nanoparticles described above in the HTL 12 or the ETL 14 is, for example, 1 to 10. As the film thickness of the HTL 12 and the film thickness of the ETL 14, conventionally known thicknesses can be adopted, and each of the film thicknesses is, for example, within a range from 1 to 150 nm.

### Second Modified Example

In addition, in the present embodiment, as indicated by S11-2 in FIG. 4, the case where the first nanoparticle film is the first QD film 31 containing the first QD 21 and the first ligand 22, the first QD film 31 being formed by drying the colloidal solution 24 has been exemplified and described. However, drying of the colloidal solution 24 is not necessarily required. The exchange of the first ligand 22 is also possible in the case where the first nanoparticle film is not a solid layer but a layer containing a liquid (QD film accompanied with a liquid).

Accordingly, the first nanoparticle film according to the present embodiment may be a film (first colloidal solution film) made of the colloidal solution 24 containing the first QD 21 (first nanoparticle), the first ligand 22, and the solvent 23 (first solvent), which is indicated by S11-1 in FIG. 4.

### Third Modified Example

In addition, in the present embodiment, the example of the method for patterning a nanoparticle film according to the present embodiment has been described with the case where the method is applied to the method for manufacturing the light-emitting element used as an example. However, the present embodiment is not limited to this example. As described above, the method for patterning a nanoparticle film according to the present embodiment can also be applied to manufacturing for a wavelength conversion member such as a wavelength conversion film in a light-emitting device such as a display device. The first nanoparticle layer pattern formed by patterning the nanoparticle film (QD film) may be, for example, the QD wavelength conversion layer in the wavelength conversion member as described above.

### Second Embodiment

Another embodiment of the disclosure will be described below with reference to FIG. 3 to FIG. 5 and FIG. 11 to FIG. 16. Note that differences from the first embodiment will be described in the present embodiment. For convenience of description, members having the same functions as the members described in the first embodiment are designated by the same reference signs, and descriptions thereof are omitted.

In the present embodiment, as an example of the method for patterning a nanoparticle film according to the present embodiment, the method for manufacturing the light-emitting element including QD light-emitting layers (EMLs) of a plurality of colors will be described as an example. Hereinafter, the case in which EMLs of three colors of a first EML, a second EML, and a third EML are patterned as a nanoparticle layer pattern according to the disclosure by using the method for patterning a nanoparticle film according to the disclosure will be described as an example.

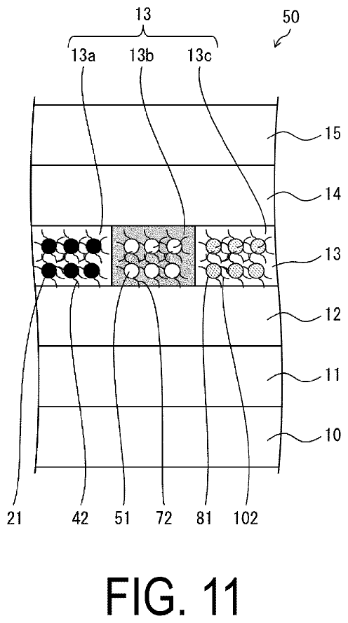

FIG. 11 is a cross-sectional view illustrating an example of a schematic configuration of main portions of a light-emitting element 50 according to the present embodiment.

The light-emitting element 50 illustrated in FIG. 11 is the same as the light-emitting element 1 illustrated in FIG. 1 except that the EML 13 includes a first EML 13a, a second EML 13b, and a third EML 13c.

The first EML 13a contains the first QD 21 (first nanoparticle) as a QD and contains the second ligand 42 as a ligand. The second EML 13b contains a second QD 51 (second nanoparticle) as a QD and contains a fourth ligand 72 as a ligand. The third EML 13c contains a third QD 81 (third nanoparticle) as a QD and contains a sixth ligand 102 as a ligand.

The second ligand 42 is positioned (coordinated) on the surface of the first QD 21 with the first QD 21 serving as a receptor. The second ligand 42 is positioned (coordinated) on the surface of the second QD 51 with the second QD 51 serving as a receptor. The sixth ligand 102 is positioned (coordinated) on the surface of the third QD 81 with the third QD 81 serving as a receptor.

The first EML 13a is formed by replacing a part of the first ligands 22 in the first QD film 31 formed by applying the colloidal solution 24 described above with the second ligands 42 and performing washing.

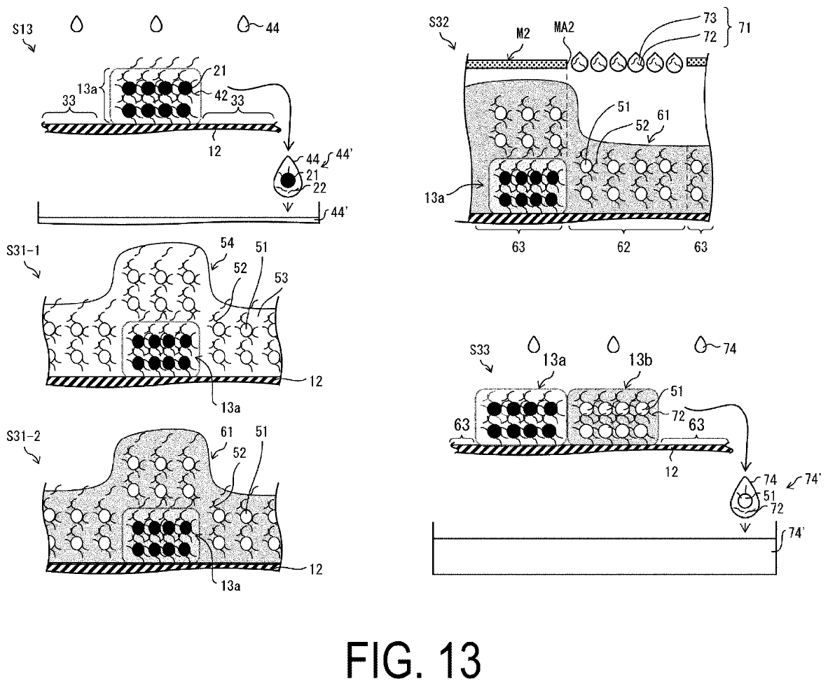

The second EML 13b is formed by replacing a part of third ligands 52 in a second QD film 61 formed by applying a colloidal solution 54 (second colloidal solution) illustrated in FIG. 13, which will be described later, with the fourth ligands 72 and performing washing. The colloidal solution 54 contains the second QD 51, the third ligand 52, and a solvent 53 (second solvent) that dissolves the third ligand 52.

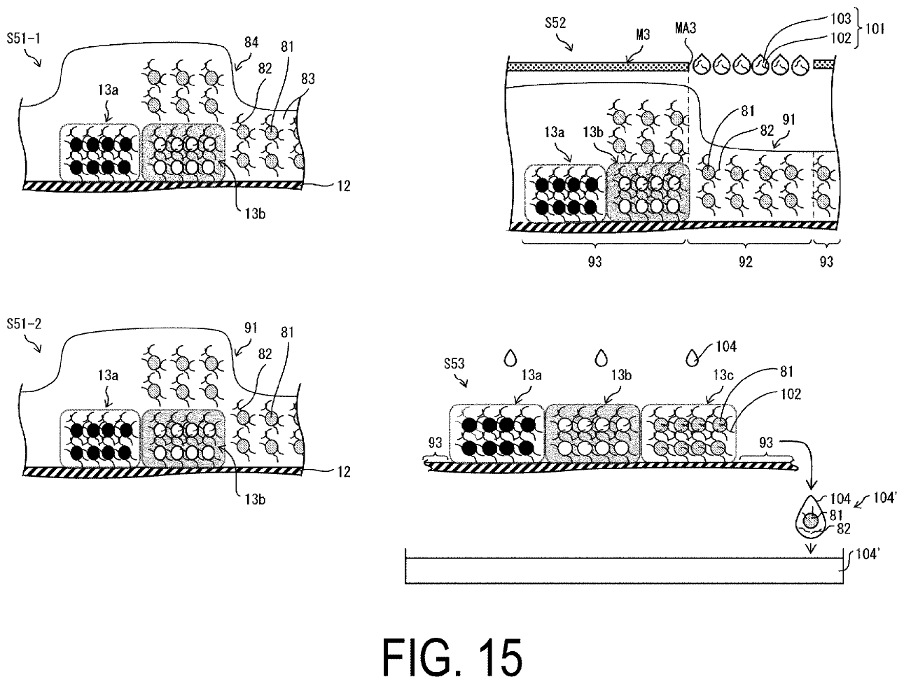

The third EML 13c is formed by replacing a part of fifth ligands 82 in a third QD film 91 formed by applying a colloidal solution 84 (third colloidal solution) illustrated in FIG. 15, which will be described later, with the sixth ligands 102 and performing washing. The colloidal solution 84 contains the third QD 81, the fifth ligand 82, and a solvent 83 (third solvent) that dissolves the fifth ligand 82.

The second QD 51 is not particularly limited as long as the second QD 51 is a QD having a light emission peak wavelength different from those of the first QD 21 and the third QD 81, and known various QDs can be used. The third QD 81 is not particularly limited as long as the third QD 81 is a QD having a light emission peak wavelength different from those of the first QD 21 and the second QD 51, and known various QDs can be used. In the present embodiment, as an example, QDs made of the same material and having different number average particle diameters are used for the first QD 21, the second QD 51, and the third QD 81, but the disclosure is not limited thereto.

As the second QD 51 and the third QD 81, a QD (for example, a QD phosphor) similar to the first QD 21 exemplified above can be used. Thus, in the first embodiment, the first QD 21 can be read as the second QD 51 or the third QD 81.

Additionally, as described above, the fourth ligand 72 is a surface modifier that modifies the surface of the second QD 51 by coordinating the second QD 51 as a receptor to the surface of the second QD 51. As the fourth ligand 72, a monomer containing at least one kind of at least two coordinating functional groups (adsorbing groups) for coordination (adsorption) to the second QD 51 is used.

As described above, the sixth ligand 102 is a surface modifier that modifies the surface of the third QD 81 by coordinating the third QD 81 as a receptor to the surface of the third QD 81. As the sixth ligand 102, a monomer containing at least one kind of at least two coordinating functional groups (adsorbing groups) for coordination (adsorption) to the third QD 81 is used.

As the fourth ligand 72 and the sixth ligand 102 that have been described, a ligand similar to the second ligand 42 given as an example above can be used. Thus, in the first embodiment, the second ligand 42 can be read as the fourth ligand 72 or the sixth ligand 102.

Accordingly, a content ratio of the first QD 21 and the second ligand 42 in the first EML 13a (the first QD 21:the second ligand 42), a content ratio of the second QD 51 and the fourth ligand 72 in the second EML 13b (the second QD 51:the fourth ligand 72), and a content ratio of the third QD 81 and the sixth ligand 102 in the third EML 13c (the third QD 81:the sixth ligand 102) are all preferably within a range from 2:0.25 to 2:6, and more preferably within a range from 2:1 to 2:4 in a weight ratio.

Similarly, the third ligand 52 is a surface modifier that modifies the surface of the second QD 51 by coordinating the second QD 51 as a receptor to the surface of the second QD 51. As the third ligand 52, a ligand containing one coordinating functional group (adsorbing group) for coordination (adsorption) to the second QD 51 is used.

In addition, the fifth ligand 82 is a surface modifier that modifies the surface of the third QD 81 by coordinating the third QD 81 as a receptor to the surface of the third QD 81. As the fifth ligand 82, a ligand containing one coordinating functional group (adsorbing group) for coordination (adsorption) to the third QD 81 is used.

As the third ligand 52 and the fifth ligand 82 that have been described above, a ligand similar to the first ligand 22 given as an example above can be used. Thus, in the first embodiment, the first ligand 22 can be read as the third ligand 52 or the fifth ligand 82.

Examples of a combination of the first QD 21, the second QD 51, and the third QD 81, which have been described above, include a combination in which the first QD 21 is a red QD that emits red light, the second QD 51 is a green QD that emits green light, and the third QD 81 is a blue QD that emits blue light. In this case, the first EML 13a is a red EML (red QD light-emitting layer), the second EML 13b is a green EML (green QD light-emitting layer), and the third EML 13c is a blue EML (blue QD light-emitting layer). However, the present embodiment is not limited to the above-described combination. In addition, as described above, although a case of patterning of EMLs of three colors will be described below as an example, EMLs of only two colors among the three colors described above may be patterned, or EMLs of four or more colors may be patterned.

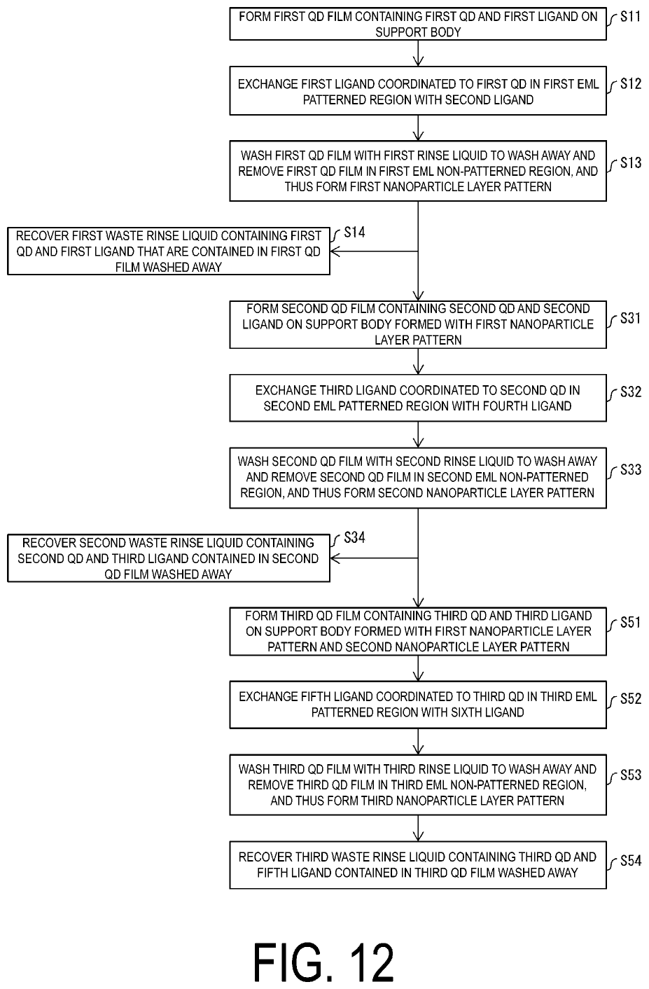

FIG. 12 is a flowchart illustrating an example of the EML forming process (step S3) using the method for patterning a nanoparticle film according to the present embodiment. FIG. 13 is a cross-sectional view illustrating a part of the EML forming process (step S3) illustrated in FIG. 12 in the order of the process.

The EML forming process (step S3) according to the present embodiment includes, for example, the first QD film forming process (step S11, the first nanoparticle film forming process), the first ligand exchanging process (step S12), the first washing process (step S13), the first rinse liquid recovering process (step S14), a second QD film forming process (step S31, a second nanoparticle film forming process), a third ligand exchanging process (step S32), a second washing process (step S33), a second rinse liquid recovering process (step S34), a third QD film forming process (step S51, a third nanoparticle film forming process), a fifth ligand exchanging process (step S52), a third washing process (step S53), and a third rinse liquid recovering process (step S54). More details will be described below.

In the method for patterning a nanoparticle film according to the present embodiment, as indicated by S11 to S13 in FIG. 12, first, step S1 to step S13 that are the same as step S11 to step S13 indicated by S11 to S13 in FIG. 3 are performed. Note that also in the present embodiment, as illustrated in FIG. 5, the first QD film forming process (step S11) includes, for example, the first colloidal solution applying process (step S21) and the first colloidal solution drying process (step S22).

However, in the present embodiment, the EML patterned region 32 is a region for patterning the first EML 13a. In the first ligand exchanging process (step S12), the first ligand 22 coordinated to the first QD 21 in the region for patterning the first EML 13a as the EML patterned region 32 is exchanged with the second ligand 42. Thus, in the present embodiment, after step S11 to step S12 indicated by S11-1 to S12-2 in FIG. 4, instead of the EML 13 indicated by S13 in FIG. 4, the first EML 13a containing the first QD 21 and the second ligand 42 is patterned as the first nanoparticle layer pattern, as indicated by S13 in FIG. 12.

Note that also in the present embodiment, as necessary, as illustrated by S13 in FIG. 12 and S13 in FIG. 13, a waste rinse liquid 44′ (the first waste rinse liquid, the first waste washing liquid) containing the first QD 21 and the first ligand 22 that have been washed away in step S13 described above and the rinse liquid 44 used for the washing is recovered (step S14, the first waste rinse liquid recovering process).

At least the first QD 21 and the first ligand 22, among the components (to be specific, the first QD 21, the first ligand 22, and the rinse liquid 44 used for the washing) contained in the waste rinse liquid 44′ recovered in step S14, can be reused for forming the first QD film 31 in step S11 in manufacturing another light-emitting element 50.

In the present embodiment, as illustrated by S31 in FIG. 12, after the first washing process (step S13), the second QD film is formed as the second nanoparticle film on the HTL 12 (strictly, on the substrate on which the HTL 12 is formed) as the support body on which the first EML 13a is patterned so as to cover the first EML 13a (step S31, the second QD film forming process).

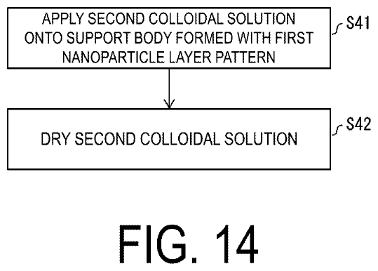

FIG. 14 is a flowchart illustrating an example of the second QD film forming process (step S31) indicated by S31 in FIG. 12.

As illustrated in FIG. 14, the second QD film forming process (step S31) includes, for example, a second colloidal solution applying process (step S41) and a second colloidal solution drying process (step S42).

In the second QD film forming process (step S31), as indicated by S31-1 in FIG. 13 and S41 in FIG. 14, first, as the second colloidal solution, the colloidal solution 54 is applied onto the HTL 12 as the support body on which the first EML 13a is patterned so as to cover the first EML 13a (step S41, the second colloidal solution applying process).

Next, as indicated by S42 in FIG. 14, the colloidal solution 54 applied onto the HTL 12 described above is dried (step S42, the second colloidal solution drying process). Thus, as indicated by S31 in FIG. 12 and S31-2 in FIG. 13, the second QD film 61 containing the second QD 51 and the third ligand 52 is formed as the second nanoparticle film on the HTL 12 described above.

Note that heating and drying such as baking may be used for drying the colloidal solution 54. A drying temperature (for example, a baking temperature) may be appropriately set according to a type of the solvent 53 so that the unnecessary solvent 53 contained in the colloidal solution 54 can be removed. Further, a drying time period may be appropriately set according to the drying temperature so that the unnecessary solvent 53 contained in the colloidal solution 54 can be removed. Thus, the drying temperature and the drying time period are not particularly limited, but can be set in a way similar to the drying temperature and the drying time period in step S22 described above, for example.

Next, as indicated by S32-1 in FIG. 13, the third ligand 52 coordinated to the second QD 51 in a second EML patterned region 62 (second nanoparticle layer patterned region) corresponding to a part of the second QD film 61 is exchanged with the fourth ligand 72 (step S32, the third ligand exchanging process).

The second EML patterned region 62 is a region for forming an EML pattern (second EML pattern) containing the second QD 51 and the fourth ligand 72. In the present embodiment, the second EML patterned region 62 is a region for patterning the second EML 13b. In order to exchange the third ligand 52 coordinated to the second QD 51 in the second EML patterned region 62 with the fourth ligand 72, as indicated by S32-1 in FIG. 13, the second solution 71 containing the fourth ligand 72 and the solvent 73 may be supplied to and brought into contact with the second EML patterned region 62. The second solution 71 is a fourth ligand supplying solution for supplying the fourth ligand 72 to the second EML patterned region 62.

As a method of supplying the second solution 71 to the second EML patterned region 62 and bringing the second solution 71 into contact with the second EML patterned region 62, for example, a method similar to the method of supplying the first solution 41 to the first EML patterned region 32 and bringing the first solution 41 into contact with the first EML patterned region 32 can be used.

Additionally, at this time, as indicated by S32 in FIG. 13, a mask M2 including an opening MA2 that exposes the second EML patterned region 62 of the second QD film 61 may be used. As described above, the mask M2 is disposed on the second QD film 61, and the second solution 71 is brought into contact with the second EML patterned region 62 through the opening MA2 of the mask M2, whereby the region where the third ligand 52 is exchanged can be easily controlled with high accuracy.

When the second solution 71 containing the fourth ligand 72 is brought into contact with the second EML patterned region 62, the third ligand 52 coordinated to the second QD 51 in the second EML patterned region 62 is exchanged with the fourth ligand 72. Thus, by permeating the second solution 71 into the second EML patterned region 62, the third ligand 52 coordinated to the second QD 51 in the second EML patterned region 62 can be exchanged with the fourth ligand 72 in the entire second EML patterned region 62.

As described above, the fourth ligand 72 contains at least one kind of at least two coordinating functional groups to be coordinated to the second QD 51. Thus, as indicated by S32-2 in FIG. 13, when the third ligand 52 coordinated to the second QD 51 in the second EML patterned region 62 is exchanged with the fourth ligand 72, a plurality of second QDs 51 in the second EML patterned region 62 is connected to each other by the fourth ligand 72. As a result, the second QD film 61 in the second EML patterned region 62 is cured and insolubilized in the rinse liquid.

Then, as necessary, the second QD film 61 described above is heated, dried and the like to remove the unnecessary solvent 73 contained in the second QD film 61 described above, and then, the second QD film 61 described above is washed with the rinse liquid 74 as indicated by S33 in FIG. 13 to remove the second QD film 61 in a region (second EML non-patterned region 63) other than the second EML patterned region 62 (step S33, the second washing process). After the washing with the rinse liquid 74 is performed in this way, the rinse liquid 74 is volatilized to pattern the second EML 13b containing the second QD 51 and the fourth ligand 72 as the second nanoparticle layer pattern according to the present embodiment as indicated by S33 in FIG. 13.

The method for washing the second QD film 61 described above is not particularly limited, and a method for washing similar to the method for washing the first QD film 31 in step S13 can be used.

Note that in the present embodiment, thereafter, as necessary, as indicated by S34 in FIG. 12 and S33 in FIG. 13, a waste rinse liquid 74′ (second waste rinse liquid, second waste washing liquid) containing the second QD 51 and the third ligand 52 that are contained in the second QD film 61 washed away in step S33 described above and the rinse liquid 74 used for the washing is recovered (step S34, the second waste rinse liquid recovering process).

Among the components contained in the waste rinse liquid 74′ recovered in step S34 (to be specific, the second QD 51, the third ligand 52, and the rinse liquid 74 used for the washing), at least the second QD 51 and the third ligand 52 can be reused for forming the second QD film 61 in step S31 in manufacturing another light-emitting element 50.

Next, as indicated by S51 in FIG. 12, after the second washing process (step S33), a third QD film is formed as a third nanoparticle film on the HTL 12 as the support body on which the first EML 13a and the second EML 13b are patterned (strictly, on the substrate on which the HTL 12 is formed) so as to cover the first EML 13a and the second EML 13b (step S51, the third QD film forming process).

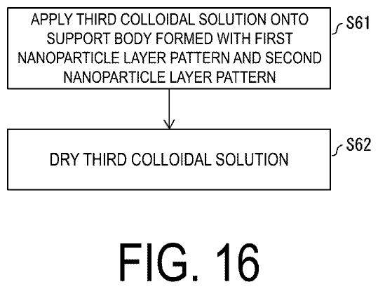

FIG. 15 is cross-sectional views illustrating another part of the EML forming process (step S3) illustrated in FIG. 12 in the order of the process. FIG. 15 illustrates the EML forming process after the process illustrated in FIG. 13. FIG. 16 is a flowchart illustrating an example of the third QD film forming process (step S51) indicated by S51 in FIG. 12.

As illustrated in FIG. 16, the third QD film forming process (step S51) includes, for example, a third colloidal solution applying process (step S61) and a third colloidal solution drying process (step S62).

In the third QD film forming process (step S51), as indicated by S51-1 in FIG. 15 and S61 in FIG. 16, first, as the third colloidal solution, the colloidal solution 84 is applied onto the HTL 12 as the support body on which the first EML 13a and the second EML 13b are patterned so as to cover the first EML 13a and the second EML 13b (step S61, the third colloidal solution applying process).

Next, as indicated by S62 in FIG. 16, the colloidal solution 84 applied onto the HTL 12 described above is dried (step S62, the third colloidal solution drying process). Thus, as indicated by S51 in FIG. 12 and S51-2 in FIG. 15, the third QD film 91 containing the third QD 81 and the fifth ligand 82 is formed as the third nanoparticle film on the HTL 12 described above.

Note that heating and drying such as baking, for example, may be used for drying the colloidal solution 84. A drying temperature (for example, a baking temperature) may be appropriately set according to a type of the solvent 83 so that the unnecessary solvent 83 contained in the colloidal solution 84 can be removed. A drying time period may be appropriately set according to the drying temperature so that the unnecessary solvent 83 contained in the colloidal solution 84 can be removed. Thus, the drying temperature and the drying time period are not particularly limited, but can be set, for example, similarly to setting of the drying temperature and the drying time period in step S22 and step S42.

Next, as indicated by S52-1 in FIG. 15, the fifth ligand 82 coordinated to the third QD 81 in the third EML patterned region 92 (third nanoparticle layer patterned region) corresponding to a part of the third QD film 91 is exchanged with the sixth ligand 102 (step S52, the fifth ligand exchanging process).

The third EML patterned region 92 is a region for forming an EML pattern (third EML pattern) containing the third QD 81 and the sixth ligand 102. In the present embodiment, the third EML patterned region 92 is a region for patterning the third EML 13c. In order to exchange the fifth ligand 82 coordinated to the third QD 81 in the third EML patterned region 92 with the sixth ligand 102, as indicated by S52-1 in FIG. 15, a third solution 101 containing the sixth ligand 102 and a solvent 103 can be supplied to the third EML patterned region 92 to bring the third solution 101 into contact with the third EML patterned region 92. The third solution 101 is a third ligand supplying solution for supplying the sixth ligand 102 to the third EML patterned region 92.

As a method of supplying the third solution 101 to the third EML patterned region 92 and bringing the third solution 101 into contact with the third EML patterned region 92, for example, a method similar to the method of supplying the first solution 41 to the first EML patterned region 32 and bringing the first solution 41 into contact with the first EML patterned region 32 can be used.

Additionally, at this time, as indicated by S52 in FIG. 15, a mask M3 including an opening MA3 that exposes the third EML patterned region 92 of the third QD film 91 may be used. As described above, the mask M3 is disposed on the third QD film 91, and the third solution 101 is brought into contact with the third EML patterned region 92 through the opening MA3 of the mask M3, which enables easy control of a region in which the exchange of the fifth ligand 82 is performed with high accuracy.

When the third solution 101 containing the sixth ligand 102 is brought into contact with the third EML patterned region 92, the fifth ligand 82 coordinated to the third QD 81 in the third EML patterned region 92 is exchanged with the sixth ligand 102. Thus, the fifth ligand 82 coordinated to the third QD 81 in the third EML patterned region 92 can be exchanged with the sixth ligand 102 in the entire third EML patterned region 92 by permeating the third solution 101 into the third EML patterned region 92.

As described above, the sixth ligand 102 contains at least one kind of at least two coordinating functional groups for coordination to the third QD 81. Thus, as indicated by S52-2 in FIG. 15, when the fifth ligand 82 coordinated to the third QD 81 in the third EML patterned region 92 is exchanged with the sixth ligand 102, a plurality of third QDs 81 in the third EML patterned region 92 is connected to each other by the sixth ligand 102. As a result, the third QD film 91 in the third EML patterned region 92 is cured and insolubilized in the rinse liquid.

Then, as necessary, an unnecessary solvent 103 contained in the third QD film 91 described above is removed by heating, drying and the like the third QD film 91 described above, and then, the third QD film 91 in a region other than the third EML patterned region 92 (the third EML non-patterned region 103) is removed by washing the third QD film 91 described above with a rinse liquid 104 as indicated by S53 in FIG. 15 (step S53, the third washing process). After the washing with the rinse liquid 104 is performed in this way, the rinse liquid 104 is volatilized to pattern the third EML 13c containing the third QD 81 and the sixth ligand 102 as the third nanoparticle layer pattern according to the present embodiment as indicated by S53 in FIG. 15.

The method for washing the third QD film 91 described above is not particularly limited, and a method for washing similar to the method for washing the first QD film 31 in step S13 and the method for washing the second QD film 61 in step S33 can be used.

Note that in the present embodiment, thereafter, as necessary, as indicated by S54 in FIG. 12 and S53 in FIG. 15, the waste rinse liquid 104′ (the third waste rinse liquid, the third waste washing liquid) containing the third QD 81 and the fifth ligand 82 that are contained in the third QD film 91 washed away in step S53 described above and the rinse liquid 104 used for the washing is recovered (step S54, the third waste rinse liquid recovering process).

Among the components contained in the waste rinse liquid 104′ recovered in step S54 (to be specific, the third QD 81, the fifth ligand 82, and the rinse liquid 104 used for the washing), at least the third QD 81 and the fifth ligand 82 can be reused for forming the third QD film 91 in step S51 in manufacturing another light-emitting element 50.

Also in the present embodiment, the solubility of the ligand alone is slightly different from the solubility of the ligand and the second QD 51 in a state where the ligand is coordinated to the second QD 51 and the solubility of the ligand and the third QD 81 in a state where the ligand is coordinated to the third QD 81.

The solvent 53 in the colloidal solution 54 is not particularly limited as long as the solvent can dissolve the second QD 51 alone and the third ligand 52 alone, and the second QD 51 and the third ligand 52 in a state where the third ligand 52 is coordinated to the second QD 51. On the other hand, when a solvent in which the second QD 51 in the second QD film 61 is dissolved is used as the solvent 73 in the second solution 71, not only ligand exchange but also dissolution of the second QD film 61 occur. Thus, the solvent 73 is not particularly limited as long as the solvent does not dissolve the second QD 51 alone and the third ligand 52 alone, and the second QD 51 and the third ligand 52 in a state where the third ligand 52 is coordinated to the second QD 51, and can dissolve the fourth ligand 72. In addition, when the fourth ligand 72 is coordinated to the second QD 51 by ligand exchange, the second QD 51 to which the fourth ligand 72 is coordinated is insolubilized and is not dissolved in any solvents. Thus, the solvent to be used as the rinse liquid 74 is not particularly limited as long as the solvent dissolves the third ligand 52 coordinated to the second QD 51 and dissolves the excessive fourth ligand 72 and third ligand 52 that are not coordinated to the second QD 51.

In addition, in the present embodiment, the solvent 83 in the colloidal solution 84 is not particularly limited as long as the solvent can dissolve the third QD 81 alone and the fifth ligand 82 alone, and the third QD 81 and the fifth ligand 82 in a state where the fifth ligand 82 is coordinated to the third QD 81. On the other hand, when a solvent in which the third QD 81 in the third QD film 91 is dissolved is used as the solvent 103 in the third solution 101, not only ligand exchange but also dissolution of the third QD film 91 occur. Thus, the solvent 103 is not particularly limited as long as the solvent does not dissolve the third QD 81 alone and the fifth ligand 82 alone, and the third QD 81 and the fifth ligand 82 in a state where the fifth ligand 82 is coordinated to the third QD 81, and can dissolve the sixth ligand 102. In addition, when the sixth ligand 102 is coordinated to the third QD 81 by ligand exchange, the third QD 81 to which the sixth ligand 102 is coordinated is insolubilized and is not dissolved in any solvents. Accordingly, the solvent to be used as the rinse liquid 104 is not particularly limited as long as the solvent dissolves the fifth ligands 82 coordinated to the third QD 81 and dissolves the excessive sixth ligand 102 and fifth ligand 82 that are not coordinated to the third QD 81.

As the solvent 53 in the colloidal solution 54 and the solvent 83 in the colloidal solution 84, a solvent similar to the solvent 23 in the colloidal solution 24 can be used. Thus, in the first embodiment, the colloidal solution 24 can be read as the colloidal solution 54 or the colloidal solution 84. In addition, in the first embodiment, the solvent 23 can be read as the solvent 53 or the solvent 83.

Thus, a concentration of the second QD 51, a concentration of the third ligand 52, and a concentration of the third ligand 52 with respect to the second QD 51 in the colloidal solution 54 may be set similarly to a concentration of the first QD 21, a concentration of the first ligand 22, and a concentration of the first ligand 22 with respect to the first QD 21 in the colloidal solution 24. Similarly, a concentration of the third QD 81, a concentration of the fifth ligand 82, and a concentration of the fifth ligand 82 with respect to the third QD 81 in the colloidal solution 84 may be set similarly to the concentration of the first QD 21, the concentration of the first ligand 22, and the concentration of the first ligand 22 with respect to the first QD 21 in the colloidal solution 24.

Further, a concentration of the fourth ligand 72 contained in the second solution 71 and a concentration of the sixth ligand 102 contained in the third solution 101 may be set similarly to the concentration of the second ligand 42 contained in the first solution 41. Further, a viscosity of the second solution 71 and a viscosity of the third solution 101 may be set similarly to a viscosity of the first solution 41.

Coordination of the fourth ligand 72 to the second QD 51, coordination of the sixth ligand 102 to the third QD 81, ligand exchange from the third ligand 52 to the fourth ligand 72, and ligand exchange from the fifth ligand 82 to the sixth ligand 102 can be checked similarly to the coordination of the second ligand 42 to the first QD 21 and the ligand exchange from the first ligand 22 to the second ligand 42.

As a result, according to the present embodiment, the method for patterning a nanoparticle film that does not require irradiation with ultraviolet light and that can suppress deterioration of the first EML 13a, the second EML 13b, and the third EML 13c that are to be formed can be provided.

### Modified Example

FIG. 11 illustrates an example in which the layers other than the first EML 13a, the second EML 13b, and the third EML 13c in the light-emitting element 50 are commonly provided to the first EML 13a, the second EML 13b, and the third EML 13c. However, among the layers in the light-emitting element 50, the function layers other than the first EML 13a, the second EML 13b, and the third EML 13c and a lower layer electrode may be provided so as to be separated from each other corresponding to the first EML 13a, the second EML 13b, and the third EML 13c. In addition, the function layers other than the first EML 13a, the second EML 13b, and the third EML 13c and a lower layer electrode may be separated by a bank (an insulating layer) (not illustrated). Additionally, the first EML 13a, the second EML 13b, and the third EML 13c may be included in different light-emitting elements from each other in a light-emitting device.

When the first EML 13a, the second EML 13b, and the third EML 13c are respectively the red EML, the green EML, and the blue EML, for example, as described above, the light-emitting element 50 can emit white light (in other words, perform white display) by causing the first EML 13a, the second EML 13b, and the third EML 13c to emit light at the same time. Alternatively, the lower layer electrode may be patterned corresponding to the first EML 13a, the second EML 13b, and the third EML 13c, and the first EML 13a, the second EML 13b, and the third EML 13c may be turned on independently of each other, so that light emission of the first EML 13a, the second EML 13b, and the third EML 13c may be individually controlled. Of course, by using QDs having light emission peak wavelengths different from those in the above-described example as QDs to be used in the first EML 13a, the second EML 13b, and the third EML 13c, light emission having light emission colors different from those in the above-described example can be achieved.

### Third Embodiment

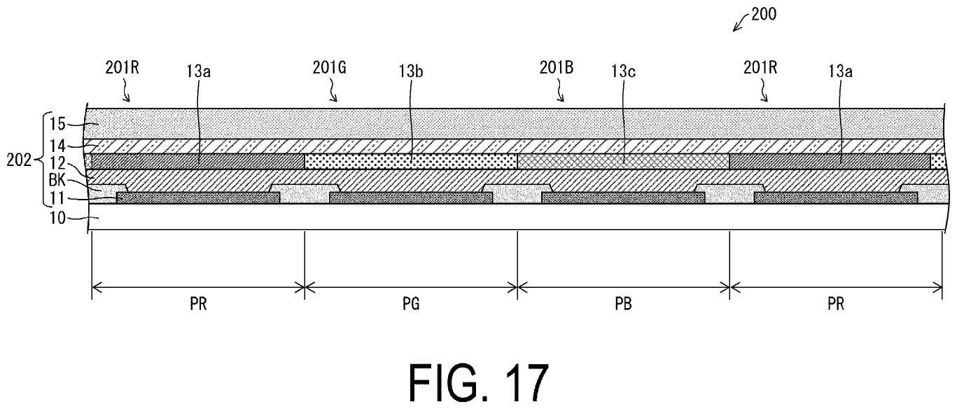

Another embodiment of the disclosure will be described below with reference to FIG. 17. Note that differences from the first and the second embodiments will be described in the present embodiment. For convenience of description, members having the same functions as the members described in the first and second embodiments are designated by the same reference signs, and descriptions thereof are omitted.

As described above, the first EML 13a, the second EML 13b, and the third EML 13c as a nanoparticle layer pattern according to the disclosure may be included in mutually different light-emitting elements in a light-emitting device. In addition, the light-emitting device including the nanoparticle layer pattern according to the disclosure may be a display device.

FIG. 17 is a cross-sectional view illustrating an example of a schematic configuration of main portions of a display device 200 according to the present embodiment.

The display device 200 includes a plurality of pixels. Each pixel is provided with a light-emitting element. The display device 200 has a configuration in which an array substrate formed with a thin film transistor layer is provided as the substrate 10, and a light-emitting element layer 202 including a plurality of light-emitting elements having different light emission wavelengths is provided on the substrate 10. The thin film transistor layer includes a plurality of thin film transistors that drive these light-emitting elements 201.

As illustrated in FIG. 17, the light-emitting element layer 202 has a structure in which each of layers of the light-emitting elements including the first EML 13a, the second EML 13b, and the third EML 13c is layered. Hereinafter, a case in which the first EML 13a, the second EML 13b, and the third EML 13c are respectively a red EML, a green EML, and a blue EML, for example, as described above will be described as an example.

The display device 200 illustrated in FIG. 17 includes, as pixels, a red pixel PR that emits red light, a green pixel PG that emits green light, and a blue pixel PB that emits blue light. A bank BK with insulating properties that partitions adjacent pixels to each other is provided as a pixel separation film between the pixels. In the display device 200, one red pixel PR, one green pixel PG, and one blue pixel PB constitute one picture element.

The display device 200 includes a red light-emitting element 201R that emits red light, a green light-emitting element 201G that emits green light, and a blue light-emitting element 201B that emits blue light as a plurality of light-emitting elements having different light emission wavelengths. In the red pixel PR, the red light-emitting element 201R is provided as the light-emitting element. In the green pixel PG, the green light-emitting element 201G is provided as the light-emitting element. In the blue pixel PB, the blue light-emitting element 201B is provided as the light-emitting element.

The red light-emitting element 201R has a configuration in which the anode electrode 11, the HTL 12, the first EML 13a, the ETL 14, and the cathode electrode 15 are layered on the substrate 10 in this order as an example. The green light-emitting element 201G has a configuration in which the anode electrode 11, the HTL 12, the second EML 13b, the ETL 14, and the cathode electrode 15 are layered on the substrate 10 in this order as an example. The blue light-emitting element 201B has a configuration in which the anode electrode 11, the HTL 12, the third EML 13c, the ETL 14, and the cathode electrode 15 are layered on the substrate 10 in this order as an example.

The anode electrode 11 that is a lower layer electrode is a pattern electrode (pattern anode electrode), and is patterned in an island shape for each light-emitting element (in other words, for each pixel). The anode electrode 11 is connected to each thin film transistor in a thin film transistor layer through a contact hole formed in a flattering film (not illustrated) provided on a surface of the thin film transistor layer. The anode electrode 11 is formed on the flattening film described above.

Each edge of the anode electrode 11 in each light-emitting element is covered with the insulating bank BK. The bank BK functions as a pixel separation film as described above, and is also used as an edge cover for covering an edge of the patterned lower layer electrode. Thus, each of the anode electrodes 11 is separated from each other by the bank BK.

On the other hand, in the example illustrated in FIG. 17, the HTL 12, the ETL 14, and the cathode electrode 15 are common layers commonly provided to each of the pixels. For example, the HTL 12 is formed on the bank BK and the anode electrode 11 so as to cover the bank BK. However, the present embodiment is not limited thereto, and the HTL 12 may be patterned, for example, in an island shape for each light-emitting element on the anode electrode 11 so as to be flush with the upper surface of the bank BK.

As described above, the first EML 13a, the second EML 13b, and the third EML 13c are separately patterned, on the support body including the anode electrode 11 and the HTL 12, in an island shape for each light-emitting element as EMLs having different light emission wavelengths from each other. As illustrated in the second embodiment, the first EML 13a, the second EML 13b, and the third EML 13c can also be patterned without providing the banks BK therebetween.

FIG. 17 illustrates, as an example, a case in which each of the pixels has a stripe arrangement. Thus, in the example illustrated in FIG. 17, the second EML 13b and the third EML 13c are individually disposed between two adjacent first EMLs 13a to each other disposed so as to be separated from each other. In the example illustrated in FIG. 17, no bank is provided between the first EML 13a and the second EML 13b and between the second EML 13b and the third EML 13c, and each of the second EML 13b and the third EML 13c is disposed adjacent to (in other words, in direct contact with) one of the two first EMLs 13a adjacent to each other.

However, the present embodiment is not limited to this, and each of the pixels may be arranged in any arrangement such as a PenTile arrangement or an S-stripe arrangement.

For example, the display device according to the present embodiment may have a PenTile arrangement in which the blue pixels PB and the green pixels PG are alternately arranged and adjacent to each other in odd-numbered rows and odd-numbered columns, the green pixels PG and the red pixels PR are alternately arranged and adjacent to each other in even-numbered rows and even-numbered columns, and the blue pixels PB and the red pixels PR are alternately arranged and adjacent to each other and the green pixels PG are adjacent to each other in an oblique direction crossing a row direction and a column direction (specifically, crossing the row direction and the column direction at an oblique angle of 45 degrees). Moreover, in this case, the EMLs in the pixels adjacent to each other may be arranged adjacent to each other without interposing the bank.

In addition, the display device according to the present embodiment may have, for example, an S-stripe arrangement in which the blue pixels PB and the green pixels PG are alternately arranged and adjacent to each other in the odd-numbered rows, the green pixels PG and the red pixels PR are alternately arranged and adjacent to each other in the even-numbered rows, the blue pixels PB and the green pixels PG are alternately arranged and adjacent to each other in the odd-numbered columns, and the green pixels PG are adjacent to each other in the even-numbered columns. Then, also in this case, the EMLs in the pixels adjacent to each other may be arranged adjacent to each other without interposing the bank.

As described above, the display device described above may have a configuration in which nanoparticle layer patterns having different light emission wavelengths from each other are arranged adjacent to each of the nanoparticle layer patterns having the same light emission wavelength between, for example, the nanoparticle layer patterns that have the same light emission wavelength and that are arranged on the support body described above so as to be separated from each other.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### REFERENCE SIGNS LIST

1, 50, 201 Light-emitting element
10 Substrate (support body)
11 Anode electrode (first electrode)
12 HTL (support body)
13 EML (first nanoparticle layer pattern)
13a First EML (first nanoparticle layer pattern)
13b Second EML (second nanoparticle layer pattern)
13c Third EML (third nanoparticle layer pattern)
15 Cathode electrode (second electrode)
21 First QD (first nanoparticle)
23, 43, 53, 73, 83, 103 Solvent
24 Colloidal solution (first colloidal solution)
31 First QD film (first nanoparticle film)
32 First EML patterned region (first nanoparticle layer patterned region)
41 First solution
42 Second ligand
44 Rinse liquid (first washing liquid)
44′ Waste rinse liquid (first waste washing liquid)
51 Second QD (second nanoparticle)
52 Third ligand
54 Colloidal solution (second colloidal solution)
61 Second QD film (second nanoparticle film)
62 Second EML patterned region (second nanoparticle layer patterned region)
71 Second solution
72 Fourth ligand
74, 104 Rinse liquid
74′, 104′ Waste rinse liquid
81 Third QD (third nanoparticle)
82 Fifth ligand
84 Colloidal solution (third colloidal solution)
91 Third QD film (third nanoparticle film)
92 Third EML patterned region (third nanoparticle layer patterned region)
101 Third solution
102 Sixth ligand
M1, M2, M3 Mask
MA1, MA2, MA3 Opening

1. A method for patterning a nanoparticle film, the method comprising:
first nanoparticle film forming of forming a first nanoparticle film on a support body, the first nanoparticle film containing a first nanoparticle and a first ligand, the first ligand containing one coordinating functional group allowing coordination to the first nanoparticle;
first ligand exchanging of bringing a first solution containing a second ligand into contact with a first nanoparticle layer patterned region that is a part of the first nanoparticle film, the second ligand containing at least one kind of at least two coordinating functional groups allowing coordination to the first nanoparticle, to exchange the first ligand coordinated to the first nanoparticle in the first nanoparticle layer patterned region with the second ligand; and
first washing of washing the first nanoparticle film with a first washing liquid to wash away and remove the first nanoparticle film in a region other than the first nanoparticle layer patterned region, the first nanoparticle film in the region not being brought into contact with the first solution, thereby forming a first nanoparticle layer pattern.

2. The method for patterning a nanoparticle film, according to claim 1,
wherein the second ligand is at least one kind of ligand selected from the group consisting of ligands represented by a following general formula (1) R¹-A¹-A²-(CH₂)ₙ—R² and a following general formula (2) R³—Z—R⁴,
in the general formula (1),
each of R¹ and R² independently represents a coordinating functional group of the at least one kind of at least two coordinating functional groups,
A¹ represents a substituted or unsubstituted —((CH₂)ₘ₁—X¹)ₘ₂-group,
A² represents a direct bond, an X² group, or a substituted or unsubstituted —((CH₂)ₘ₃—X²)ₘ₄-group,
X¹ and X² represent polar bonding groups different from each other,
each of n, m1, and m3 independently represents an integer of 1 to 4, and
each of m2 and m4 independently represents an integer of 1 to 10, and
in the general formula (2),
each of R³ and R⁴ independently represents a coordinating functional group of the at least one kind of at least two coordinating functional groups, and
Z represents a substituted or unsubstituted alkylene group having 1 to 10 carbons or a substituted or unsubstituted unsaturated hydrocarbon group having 2 to 10 carbons.

3. The method for patterning a nanoparticle film, according to claim 2,
wherein the A² is a direct bond, and
2≤m1×m2+n≤20 is satisfied.

4. (canceled)

5. The method for patterning a nanoparticle film, according to claim 2,
wherein the A² is —((CH₂)ₘ₃—X²)ₘ₄-group, and
2≤m1×m2+m3×m4+n≤20 is satisfied.

6. (canceled)

7. The method for patterning a nanoparticle film, according to claim 2,
wherein the Z represents a substituted or unsubstituted alkylene group having 4 to 10 carbons or a substituted or unsubstituted unsaturated hydrocarbon group having 4 to 10 carbons.

8. The method for patterning a nanoparticle film, according to claim 2,
wherein each of the polar bonding groups is selected from the group consisting of an ether bonding group, a sulfide bonding group, an imine bonding group, an ester bonding group, an amide bonding group, and a carbonyl group.

9. The method for patterning a nanoparticle film, according to claim 2,
wherein the coordinating functional groups are independent of each other, and each of the coordinating functional groups is a thiol group, an amino group, a carboxyl group, a phosphone group, a phosphine group, or a phosphine oxide group.

10. The method for patterning a nanoparticle film, according to claim 1,
wherein the second ligand is at least one kind of ligand selected from the group consisting of 1,2-ethanedithiol, 1,2-propanedithiol, 1,3-propanedithiol, 1,2-butanedithiol, 1,3-butanedithiol, 1,4-butanedithiol, 2,3-butanedithiol, 1,6-hexanedithiol, 1,8-octanedithiol, 1,2-propanediamine, 1,3-propanediamine, 1,4-butanediamine, 3-amino-5-mercapto-1,2,4-triazole, 2-aminobenzenethiol, toluene-3,4-dithiol, dithioerythritol, dihydrolipoic acid, thiolactic acid, 3-mercaptopropionic acid, 1-amino-3,6,9,12,15,18-hexaoxaheneicosan-21-oic acid, 2-[2-(2-aminoethoxy)ethoxy]acetic acid, 2,2′-(ethylenedioxy)diethanethiol, 2,2′-oxydiethanethiol, (12-phosphonododecyl)phosphonic acid, 11-mercaptoundecylphosphonic acid, 11-phosphonoundecanoic acid, and ethylene glycol bis(3-mercaptopropionate).

11. The method for patterning a nanoparticle film, according to claim 1,
wherein the first nanoparticle film is a first colloidal solution film containing the first ligand, the first nanoparticle, and a first solvent.

12. The method for patterning a nanoparticle film, according to claim 1,
wherein the first nanoparticle film forming includes
first colloidal solution applying of applying a first colloidal solution containing the first ligand, the first nanoparticle, and a first solvent onto the support body, and
first colloidal solution drying of drying the first colloidal solution applied onto the support body.

13-16. (canceled)

17. The method for patterning a nanoparticle film, according to claim 1,
wherein the first solution further contains a polar solvent.

18-21. (canceled)

22. The method for patterning a nanoparticle film, according to claim 1,
wherein the first washing liquid is a polar solvent.

23-25. (canceled)

26. The method for patterning a nanoparticle film, according to claim 1,
wherein the first solution further contains a non-polar solvent.

27-28. (canceled)

29. The method for patterning a nanoparticle film, according to claim 1,
wherein a concentration of the second ligand contained in the first solution is within a range from 0.01 mol/L to 2.0 mol/L.

30. The method for patterning a nanoparticle film, according to claim 1,
wherein a viscosity of the first solution is within a range from 0.5 mPa·s to 500 mPa·s.

31-47. (canceled)

48. A method for manufacturing a light-emitting device, the light-emitting device including a first electrode and a second electrode, and, between the first electrode and the second electrode, at least one layer including a nanoparticle layer pattern containing a nanoparticle, the method comprising:
forming the at least one layer of the at least one layer including the nanoparticle layer pattern by the method for patterning a nanoparticle film according to claim 1.

49. A light-emitting device comprising:
a support body; and
a plurality of first nanoparticle layer patterns spaced apart from each other on the support body,
wherein each of the plurality of first nanoparticle layer patterns includes a plurality of first nanoparticles and a ligand, the ligand containing at least one kind of at least two coordinating functional groups allowing coordination to the plurality of first nanoparticles.

50. The light-emitting device according to claim 49, further comprising:
a second nanoparticle layer pattern disposed on the support body between first nanoparticle layer patterns adjacent to each other of the plurality of first nanoparticle layer patterns,
wherein the second nanoparticle layer pattern contains a plurality of second nanoparticles, and a ligand containing at least one kind of at least two coordinating functional groups allowing coordination to the plurality of second nanoparticles.

51. The light-emitting device according to claim 50,
wherein the second nanoparticle layer pattern is disposed adjacent to at least one first nanoparticle layer pattern of the first nanoparticle layer patterns adjacent to each other.

52. The light-emitting device according to claim 50,
wherein the second nanoparticle layer pattern is disposed adjacent to one first nanoparticle layer pattern of the first nanoparticle layer patterns adjacent to each other,
a third nanoparticle layer pattern is further provided on the support body between the second nanoparticle layer pattern and the other first nanoparticle layer pattern of the first nanoparticle layer patterns adjacent to each other, the third nanoparticle layer pattern being disposed adjacent to each of the second nanoparticle layer pattern and the other first nanoparticle layer pattern, and
the third nanoparticle layer pattern contains a plurality of third nanoparticles, and a ligand containing at least one kind of at least two coordinating functional groups allowing coordination to the plurality of third nanoparticles.
